(19) United States
(12) Patent Application Publication
(10) Pub. No.: US 2025/0393129 A1
(43) Pub. Date: Dec. 25, 2025

(54) SANDWICH STRUCTURE POWER SUPPLY MODULE FOR IMPROVED POWER EFFICIENCY AND TRANSIENT RESPONSE

(71) Applicant: Monolithic Power Systems, Inc., Kirkland, WA (US)

(72) Inventors: Ting Ge, San Jose, CA (US); Fengchun He, Hangzhou (CN); Wenyang Huang, Hangzhou (CN); Yingxin Zhou, Hangzhou (CN)

(21) Appl. No.: 19/304,347

(22) Filed: Aug. 19, 2025

Related U.S. Application Data
(63) Continuation-in-part of application No. 18/447,721, filed on Aug. 10, 2023.
Application No. 18/447,721 is a continuation-in-part of application No. 17/197,394, filed on Mar. 10, 2021, now Pat. No. 12,309,929.
Application No. 17/197,394 is a continuation-in-part of application No. 17/870,555, filed on Jul. 21, 2022, now Pat. No. 12,120,822.
Application No. 17/870,555 is a continuation-in-part of application No. 18/090,734, filed on Dec. 29, 2022, now Pat. No. 12,453,061.
Application No. 17/870,555 is a continuation-in-part of application No. 17/678,172, filed on Feb. 23, 2022, now Pat. No. 12,095,369.

(51) Int. Cl. H05K 1/18; H01F 27/24; H01F 27/28

(52) U.S. Cl. CPC H05K 1/181; H01F 27/24; H01F 27/28; H05K 2201/1003; H05K 2201/10166

(57) ABSTRACT

A power supply module comprises an inductor pack, a top substrate disposed above the inductor pack, a first power IC die and a second power IC die disposed above the inductor pack, and a support structure disposed below the inductor pack. The inductor pack has a magnetic core, and a first winding and a second winding which pass through the magnetic core. The top substrate has a bottom surface attached to the inductor pack. The first power IC die is electrically connected to the first winding, and the second power IC die is electrically connected to the second winding. The support structure electrically connects the power supply module to an external circuit. A cavity is formed below the inductor pack for accommodating passive components, and the cavity is at least partially surrounded by the support structure.

### CROSS-REFERENCE TO RELATED APPLICATIONS

The present application is a continuation-in-part of U.S. application Ser. No. 18/447,721 filed on Aug. 10, 2023, which is a continuation-in-part of U.S. application Ser. No. 17/197,394 filed on Mar. 10, 2021, U.S. application Ser. No. 17/870,555 filed on Jul. 21, 2022, and U.S. application Ser. No. 18/090,734 filed on Dec. 29, 2022, wherein U.S. application Ser. No. 17/870,555 is a continuation-in-part of U.S. application Ser. No. 17/678,172 filed on Feb. 23, 2022. All of these related applications are incorporated herein by reference in their entirety.

### BACKGROUND OF THE INVENTION

### 1. Field of the Invention

The present invention relates generally to electronic circuits, and more particularly but not exclusively to power modules.

### 2. Description of Related Art

Power converter, as known in the art, converts an input power to an output power for providing a load with required voltage and current. Multi-phase power converter comprising a plurality of paralleled power stages operating out of phase has lower output ripple voltage, better transient performance and lower ripple-current-rating requirements for input capacitors. They are widely used in high current and low voltage applications, such as server, microprocessor.

With the development of modern GPUs (Graphics Processing Units), and CPUs (Central Processing Units), increasingly high load current is required to achieve better processor performance. However, the size of microprocessor needs to become smaller. Higher current and smaller size put more challenges to the heat conduction. Therefore, high-power density and high-efficiency power converters with excellent heat dissipation path are necessary.

### SUMMARY OF THE INVENTION

It is an object of the present invention to provide a sandwich structure power supply module with improved power efficiency and transient response.

Embodiments of the present invention are directed to a power supply module, comprising an inductor pack, a top substrate disposed above the inductor pack, a first power IC die and a second power IC die disposed above the inductor pack, a support structure disposed below the inductor pack, and a cavity formed below the inductor pack. The inductor pack has a magnetic core, a first winding and a second winding, wherein the first winding and the second winding pass through the magnetic core. The top substrate has a bottom surface attached to the inductor pack. The first power IC die is electrically connected to the first winding and the second power IC die is electrically connected to the second winding. The support structure is capable of electrically connecting the power supply module to an external circuit. The cavity is at least partially surrounded by the support structure, and the cavity is capable of accommodating passive components.

Embodiments of the present invention are directed to a power supply module, comprising an inductor pack, a top substrate disposed above the inductor pack, a first pair of power switches and a second pair of power switches. The first pair of power switches and the second pair of power switches are disposed on or embedded in the top substrate. The first pair of power switches and the second pair of power switches are electrically connected between an input voltage and a reference ground. A common node of the first pair of power switches is electrically connected to the first end of the first winding, and a common node of the second pair of power switches is electrically connected to the first end of the second winding. A cavity is formed below the inductor pack for accommodating passive components.

Embodiments of the present invention are directed to a power supply system, comprising a motherboard having a first surface and a second surface opposite each other, a load disposed on the first surface of the motherboard, and a power supply module and a plurality of capacitors disposed on the second surface of the motherboard. Each of the plurality of capacitors having a first end and a second end. The power supply module comprises a top substrate, a first pair of power switches and a second pair of power switches disposed on or embedded in the top substrate, and at least one cavity formed below the top substrate. The first pair of power switches and the second pair of power switches are electrically connected between an input voltage and a reference ground, a common node of the first pair of power switches is electrically connected to a first end of a first inductor, and a common node of the second pair of power switches is electrically connected to a first end of a second inductor. The plurality of capacitors are disposed in the at least one cavity. The first ends of the plurality of capacitors are electrically connected to the reference ground, and a second end of the first inductor and a second end of the second inductor are electrically connected to the second ends of the plurality of capacitors to provide an output voltage to the load.

These and other features of the present invention will be readily apparent to persons of ordinary skill in the art upon reading the entirety of this disclosure, which includes the accompanying drawings and claims.

### BRIEF DESCRIPTION OF THE DRAWINGS

The present invention can be further understood with reference to following detailed description and appended drawings, wherein like elements are provided with like reference numerals. These drawings are only for illustration purpose, thus may only show part of the devices and are not necessarily drawn to scale.

FIG. 1 shows a schematic diagram of a power module 100 in accordance with an embodiment of the present invention.

FIG. 2 shows a top view, a bottom view, and a side view of a physical layout of the power module 100 of FIG. 1 in accordance with an embodiment of the present invention.

FIG. 3 shows a cross-sectional view of a substrate 200 of the power module 100 in accordance with an embodiment of the present invention.

FIG. 4 shows a top view of a physical layout of a power module 400 in accordance with an embodiment of the present invention.

FIG. 5 shows a side view of the power module 400 of FIG. 4 in accordance with an embodiment of the present invention.

FIG. 6 shows a cross-sectional view of the power module 400 in accordance with an embodiment of the present invention.

FIG. 7 shows a top surface of an output capacitor substrate layer 453 in accordance with an embodiment of the present invention.

FIG. 8 is a schematic block diagram of a two-stage power supply architecture 500 in accordance with an embodiment of the present invention.

FIG. 9 is a schematic circuit diagram of a switched tank converter 600 in accordance with an embodiment of the present invention.

FIG. 10 is a schematic block diagram of a multi-phase voltage regulator 700 in accordance with an embodiment of the present invention.

FIG. 11A is a schematic diagram of a power module 800 in accordance with an embodiment of the present invention.

FIG. 11B is a schematic diagram of a power module 802 in accordance with an embodiment of the present invention.

FIG. 12 is a schematic diagram of a side view of a power module 900 in accordance with an embodiment of the present invention.

FIG. 13A is a schematic diagram of a side view of a first power module 1000 in accordance with an embodiment of the present invention.

FIG. 13B is a schematic diagram of a side view of a first power module 1002 in accordance with another embodiment of the present invention.

FIG. 13C is a schematic diagram of a side view of a first power module 1004 in accordance with yet another embodiment of the present invention.

FIG. 14 is a schematic diagram of a plan view a power module 1100 in accordance with an embodiment of the present invention.

FIG. 15 is a schematic diagram of a side view of a second power module 1200 in accordance with an embodiment of the present invention.

FIG. 16 is a schematic diagram of a side view of a second power module 1302 in accordance with another embodiment of the present invention.

FIG. 17 is a schematic diagram of a plan view a first PCB 1310 of a second power module in accordance with an embodiment of the present invention.

FIG. 18A is a schematic diagram of a power module 1500 in accordance with an embodiment of the present invention.

FIG. 18B is a schematic diagram of a side view of the power module 1500 in accordance with an embodiment of the present invention.

FIG. 19 schematically shows a prior art multi-phase power converter 10A which comprises a controller 101, N power devices 103 and N inductors L1 for supplying power to a load 104.

FIG. 20 shows a sandwich structure power supply module 20A for a dual-phase power converter in accordance with an embodiment of the present invention.

FIG. 21 shows the disassembled view of an inductor pack 30 in accordance with an embodiment of the present invention.

FIG. 22 shows the disassembled view of an inductor pack 40 in accordance with an embodiment of the present invention.

FIG. 23 shows the disassembled view of an inductor pack 50 in accordance with an embodiment of the present invention.

FIG. 24 shows a magnetic core 60 in accordance with an embodiment of the present invention.

FIG. 25 shows a magnetic core 70 in accordance with an embodiment of the present invention.

FIG. 26 schematically shows a multi-phase power converter 10B which comprises the controller 101, N power devices 103, N inductors L1, and N output capacitors 107 for supplying power to the load 104.

FIG. 27 shows a sandwich structure power supply module 20B with output capacitors embedded for a dual-phase power converter in accordance with an embodiment of the present invention.

FIG. 28 shows a top view of the power supply module 20B of FIG. 27 in accordance with an embodiment of the present invention.

FIG. 29 shows a side view of the power supply module 20B of FIG. 27 in accordance with an embodiment of the present invention.

FIG. 30 shows a cross-sectional view of the power supply module 20B of FIG. 27 in accordance with an embodiment of the present invention.

FIG. 31 shows a top view of the output capacitor layer 210 in accordance with an embodiment of the present invention.

FIG. 32 shows a bottom view of the power supply module 20B of FIG. 27 in accordance with an embodiment of the present invention.

FIG. 33 shows a sandwich structure power supply module 20C with output capacitors embedded for a dual-phase power converter in accordance with another embodiment of the present invention.

FIG. 34 schematically shows a top view of a power supply module 20D in accordance with another embodiment of the present invention.

FIG. 35 schematically shows a cross-sectional view of the power supply module 20D of FIG. 34 in accordance with an embodiment of the present invention.

FIG. 36 schematically shows a side view, a cross-sectional view, and a bottom view of a power supply module 80 in accordance with an embodiment of the present invention.

FIG. 37 schematically shows a 3D view of a power supply module 80A in accordance with an embodiment of the present invention.

FIG. 38 schematically shows a 3D view of a power supply module 80B in accordance with an embodiment of the present invention.

FIG. 39 schematically shows a 3D view of a power supply module 80C in accordance with an embodiment of the present invention.

FIG. 40 schematically shows a 3D view of a power supply module 80D in accordance with an embodiment of the present invention.

FIG. 41 schematically shows a side view of a power supply module 82 in accordance with an embodiment of the present invention.

FIG. 42 schematically shows a 3D view of the power supply module 82 of FIG. 41 in accordance with an embodiment of the present invention.

FIG. 43 schematically shows a 3D view of the power supply module 82 of FIG. 41 in accordance with an embodiment of the present invention and taken from another perspective.

FIG. 44 schematically shows a cross-sectional view and a bottom view of the power supply module 82 of FIG. 41 in accordance with an embodiment of the present invention.

FIG. 45 schematically shows a cross-sectional view and a bottom view of the power supply module 82 of FIG. 41 in accordance with another embodiment of the present invention.

FIG. 46 schematically shows a side view of a power supply module 84A in accordance with an embodiment of the present invention.

FIG. 47 schematically shows a side view of a power supply module 84B in accordance with an embodiment of the present invention.

FIG. 48 schematically shows a side view of a power supply module 84C in accordance with an embodiment of the present invention.

FIG. 49 shows a cross-sectional view of a physical layout of a power supply system 90A in accordance with an embodiment of the present invention.

FIG. 50 shows a bottom view of the physical layout of the power supply system 90A in accordance with an embodiment of the present invention.

FIG. 51 shows a cross-sectional view of a physical layout of a power supply system 90B in accordance with another embodiment of the present invention.

FIG. 52 shows a cross-sectional view of a physical layout of a power supply system 90C in accordance with yet another embodiment of the present invention.

FIG. 53 shows a cross-sectional view of a physical layout of a power supply system 90D in accordance with yet another embodiment of the present invention.

FIG. 54 shows a bottom view of the physical layout of the power supply system 90D in accordance with an embodiment of the present invention.

FIG. 55 shows waveforms 912 of an output current and output voltages in accordance with an embodiment of the present invention.

### DETAILED DESCRIPTION

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

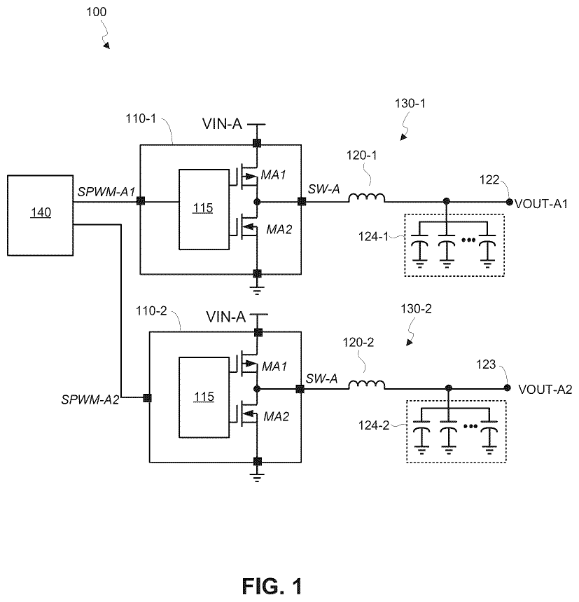

FIG. 1 shows a schematic diagram of a power module 100 in accordance with an embodiment of the present invention. In the example of FIG. 1, the power module 100 has two power converters 130 (i.e., 130-1, 130-2), with each power converter 130 comprising an output inductor 120 (i.e., 120-1, 120-2), an output capacitor 124 (i.e., 124-1, 124-2), and a monolithic integrated circuit (IC) switch block 110 (i.e., 110-1, 110-2). In one embodiment, an output capacitor 124 comprises a plurality of discrete capacitors that are connected in parallel. In the example of FIG. 1, a power converter 130 is a buck converter. As can be appreciated, a power converter 130 may also be configured as a boost converter or other type of power converter depending on the application.

Each of the power converters 130-1 and 130-2 receives an input voltage VIN-A to generate an output voltage VOUT-A (i.e., VOUT-A 1, VOUT-A 2). The output voltages of the power converters 130-1 and 130-2 may be connected together and interleaved to generate a multiphase output voltage. For example, an output voltage node 122 and an output voltage node 123 may be connected together, with each power converter 130 providing a phase of a multiphase output voltage. In that example, the power module 100 may include additional power converters to add more phases.

An output capacitor 124 is connected to each output voltage node. In the example of FIG. 1, an output capacitor 124-1 has a first end that is connected to the output voltage node 122 and a second end that is connected to power ground. Similarly, an output capacitor 124-2 has a first end that is connected to the output voltage node 123 and a second end that is connected to power ground. Other capacitors (e.g., input capacitors, supply capacitors) and other components not necessary to the understanding of the invention are not shown in FIG. 1 for clarity of illustration.

In one embodiment, a switch block 110 is implemented using an MP86976 Intelli-Phase™ Solution monolithic IC, which is commercially-available from Monolithic Power Systems, Inc. Other suitable monolithic IC's may also be used without detracting from the merits of the present invention. A switch block 110 has, integrated therein, a driver 115 and a pair of switches MA1, MA2 (e.g., Metal-Oxide-Semiconductor Field-Effect Transistor (MOSFET)). Other circuits for implementing the driver 115, such as an auxiliary 3.3V power supply circuit, are not shown for clarity of illustration. As shown in FIG. 1, a switch block 110 has a first pin for receiving a pulse width modulation (PWM) signal, a second pin for receiving an input voltage VIN-A, a third pin for connecting to power ground, and a fourth pin that is connected to a switch node SW-A formed by the switches MA1, MA2. The drain of the switch MA1 is connected to the input voltage VIN-A and the source of the switch MA2 is connected to power ground. The source of the switch MA1 is connected to the drain of the switch MA2 at the switch node SW-A.

Generally speaking, PWM control is well-known in the art. Briefly, an external PWM controller 140 generates a PWM signal, which is received by a driver 115 at the first pin of the switch block 110. The driver 115 turns the switches MA1, MA2 ON and OFF in accordance with the PWM signal. Turning the switch MA1 ON while turning the switch MA2 OFF connects the input voltage VIN-A to the switch node SW-A (by way of the switch MA1), whereas turning the switch MA1 OFF while turning the switch MA2 ON connects the switch node SW-A to power ground (by way of the switch MA2). A first end of an output inductor 120 is connected to the switch node SW-A and a second end of the output inductor 120 is connected to an output voltage node (i.e., 122, 123) where an output voltage VOUT-A is developed. In the example of FIG. 1, the PWM controller 140 generates the PWM signals SPWM-A1, SPWM-A2 such that a corresponding output voltage VOUT-A is maintained in regulation. Other circuits for implementing the PWM control, such as sense circuits, are not shown for clarity of illustration.

The input voltage VIN-A, output voltage VOUT-A, and switching frequency of the switches MA1, MA2 depend on the particulars of the monolithic integrated circuit (IC) switch block 110. In one embodiment where the monolithic IC switch block 110 is implemented using the aforementioned MP86976 Intelli-Phase™ Solution monolithic IC, the input voltage VIN-A is in the range of 3V to 7V, the output voltage VOUT-A is in the range of 0.4V to 2V (e.g., 0.8V), and the switching frequency of the switches MA1, MA2 is in the range of 1 MHz to 2 MHz (e.g., 1.5 MHz). The relatively low input voltage VIN-A and relatively high switching frequency of the switches MA1, MA2 allow for a relatively small physical size of the output inductor 120 (e.g., 2.5 mm×5 mm×1.2 mm). As will be more apparent below, the output inductor 120 may be embedded within the substrate of the power module 100 to achieve a low profile.

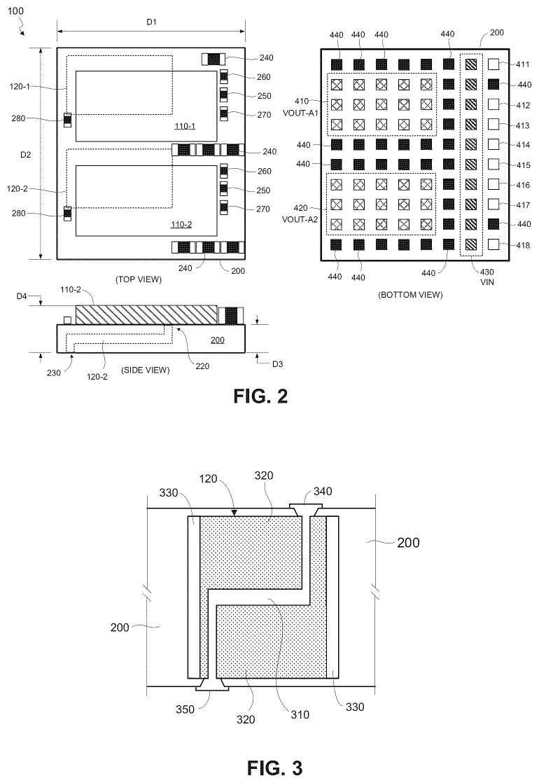

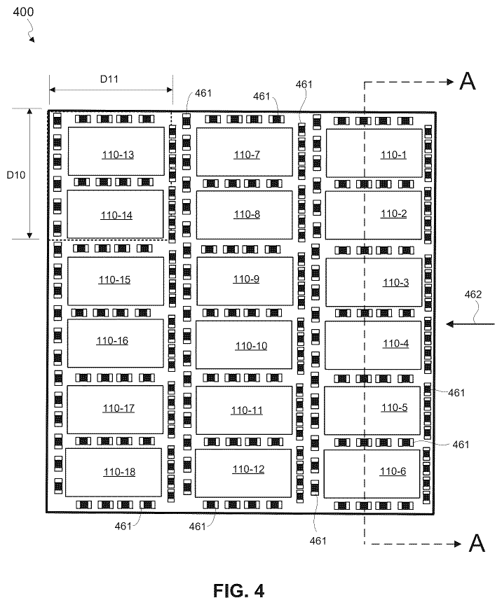

FIG. 2 shows, from the upper left hand corner in clock-wise direction, a top view, a bottom view, and a side view of a physical layout of the power module 100 in accordance with an embodiment of the present invention. The power module 100 has a substrate 200, which in one embodiment is that of a printed circuit board (PCB). The top view of the substrate 200 shows the “component side” of the substrate 200, whereas the bottom view shows the bottom side of the substrate 200. In the example of FIG. 2, the switch blocks 110, capacitors, and other components are mounted on the component side. In other embodiments, as will be later explained beginning with FIG. 4, output capacitors are disposed within a separate output capacitor substrate layer.

In the example of FIG. 2, the bottom side, which is opposite the component side, has a plurality of pins that connect nodes of the power module 100 to components that are external to the power module 100, such as a PWM controller, etc. A pin may be a pad or other means for electrically connecting nodes and components. A pin may have a square (e.g., as in a land grid array), round (e.g., as in a ball grid array), or other shape. The power module 100 may be employed as part of a power supply (not shown). The pins of the power module 100 may be connected to corresponding sockets on a substrate of the power supply.

The top view of the power module 100 shows the switch block 110-1, switch block 110-2, and various capacitors mounted on the component side, such as input capacitors (e.g., see 240), capacitors of RC filters of supply voltages for internal digital logic control (e.g., 250, 270), bootstrap capacitors (e.g., see 260), filter capacitors of supply voltages for switch drivers (e.g., see 280), etc. As can be appreciated, the number and type of capacitors on the power module 100 depend on the particulars of the application. Generally, the capacitors on the power module 100 have relatively low capacitance. In the example of FIG. 2, a switch block 110 is the tallest component on the substrate 200. In one embodiment, the substrate 200 has a width D1 of about 8 mm; a length D2 of about 9 mm, and a substrate thickness D3 of about 1.5 mm. In one embodiment, a height D4 from the bottom surface of the substrate 200 to the topmost surface of a switch block 110 is 2.3 mm.

The output inductors 120-1 and 120-2, which are represented by dotted lines in FIG. 2, are embedded within the substrate 200. A first end of an output inductor 120 (see 220) is connected to a switch node of a corresponding switch block 110, and a second end of the output inductor 120 (see 230) is connected to a corresponding output voltage node. The relatively low inductance of each of the output inductors 120-1 and 120-2 in conjunction with the layout of the power module 100 allow the output inductors 120-1 and 120-2 to be embedded within the substrate 200, thereby lowering the profile of the power module 100. In one embodiment, the height D4 of the power module 100 is 2.3 mm and at most 5 mm.

In the example of FIG. 2, each pin of the power module 100 has a square shape, e.g., 0.45 mm×0.45 mm square. The pins that are connected to power ground, some of which are labeled as “440”, are depicted in black. Not all of the ground pins are labeled for clarity of illustration. The pins that are connected to the output voltage node 122 (shown in FIG. 1), where the output voltage VOUT-A 1 is developed, are collectively labeled as “410”; the pins that are connected to the output voltage node 123 (shown in FIG. 1), where the output voltage VOUT-A 2 is developed, are collectively labeled as “420”; and the pins that are connected to receive the input voltage VIN-A are collectively labeled as “430”. Pin 411 is connected to receive a PWM signal to the switch block 110-1; pin 418 is connected to receive a PWM signal to the switch block 110-2; pin 412 is connected to provide a current monitor signal from the switch block 110-1; pin 417 is connected to provide a current monitor signal from the switch block 110-2; pin 413 is connected to provide a temperature monitoring signal from the switch block 110-1; pin 416 is connected to provide a temperature monitoring signal from the switch block 110-2; pin 414 is connected to receive a VCC supply voltage; and pin 415 is connected to receive an enable signal. As can be appreciated, the pinout of the power module 100 depends on implementation details, such as the particular switch block 110 employed. The arrangement of the pins on the bottom surface of the substrate 200 may vary to suit particular applications.

FIG. 3 shows a cross-sectional view of the substrate 200 in accordance with an embodiment of the present invention. FIG. 3 provides a schematic illustration of an output inductor 120 and is not to scale. In one embodiment, the output inductor 120 is a one turn inductor. The output inductor 120 may also have a few number of turns. The output inductor 120 comprises a conductor 310 and a magnetic core 320 that surrounds the conductor 310. In one embodiment, the conductor 310 comprises copper and the magnetic core 320 comprises a suitable core material, such as ferrite or powder iron. A gap 330 is between the magnetic core 320 and the substrate material, which in one embodiment comprises a PCB substrate. Generally speaking, a PCB is a laminated sandwich structure of conductive layers (e.g., copper) and insulating/dielectric layers (e.g., fiberglass epoxy laminate). The gap 330 may be an air gap that is filled with epoxy molding compound. A first end of the conductor 310 (see 340) comes out of the component side of the substrate 200 to connect to the switch node of a corresponding switch block 110, and a second end of the conductor 310 (see 350) comes out of the bottom side of the substrate 200 to a pin that is connected to a corresponding output voltage node.

In one embodiment, the output inductor 120 has an inductance less than 100 nH. As can be appreciated, the inductance of the output inductor 120 may vary depending on the volume of the substrate 200. Larger substrates allow physically larger inductors to be embedded. For example, with a thickness D3 (shown in FIG. 2) of 1.5 mm, the output inductor 120 may have dimensions of 2.5 mm×5 mm×1.2 mm with an inductance of about 30 nH.

FIG. 4 shows a top view of a physical layout of the power module 400 in accordance with an embodiment of the present invention. The top view of FIG. 4 shows a topmost surface of the PCB of the power module 400 where switch blocks 110 (i.e., 110-1, 110-2, . . . , 110-18), capacitors 461 (e.g., input capacitors, bootstrap capacitors, filter capacitors, supply capacitors, etc.), and other components (not shown) of the power module 400 are mounted. Each of the switch blocks 110 of the power module 400 may be employed in a power converter 130 as described in connection with FIG. 1. Generally speaking, the number of power converters on a power module, and thus the number of switch blocks, depend on the particulars of the application.

In the example of FIG. 4, the switch blocks 110 are physically arranged in groups of two (e.g., switch blocks 110-1 and 110-2 as one group; switch blocks 110-13 and 110-14 as another group; etc.), with each group of switch blocks having a length D10 of 8 mm and a width D11 of 8 mm. The switch blocks 110 may be configured to generate one or more output voltages. For example, the output voltage node of the switch block 110-1 may provide a first output voltage, and the output voltage node of the switch block 110-2 may provide a second output voltage, with each of the first and second output voltages being independent, separate output voltages. As another example, the output voltage nodes of the switch blocks 110-1 to 110-12 may be tied together to provide a first multiphase output voltage, and the output voltage nodes of the switch blocks 110-13 to 110-18 may be tied together to provide a second multiphase output voltage. All of the output voltages of the switch blocks 110 may also be tied together to generate a single multi-phase output voltage.

The power module 400 has 18 switch blocks 110 for illustration purposes only. As can be appreciated, fewer or more switch blocks 110 may be employed depending on the number of power converters provided by the power module 400. The specific layout of the components of the power module 400 may be configured to suit application details.

The power module 400 may be employed in various applications including graphics processing unit (GPU), central processing unit (CPU), application-specific integrated circuit (ASIC), etc. applications. During fast load transients, a sufficient number of output capacitors is required to limit output voltage undershoot and overshoot. However, output capacitors consume a lot of board space and decrease circuit density. This problem is especially troublesome in applications with a fixed board form factor, where the board space required by the output capacitors reduces the number of power converters available on the power module, thereby limiting the power that can be delivered to GPUs, CPUs, etc. In embodiments of the present invention, to conserve board space, an output capacitor of a power converter 130 is implemented by a plurality of parallel-connected discrete capacitors embedded within an output capacitor substrate layer of the PCB instead of on a topmost surface of the PCB.

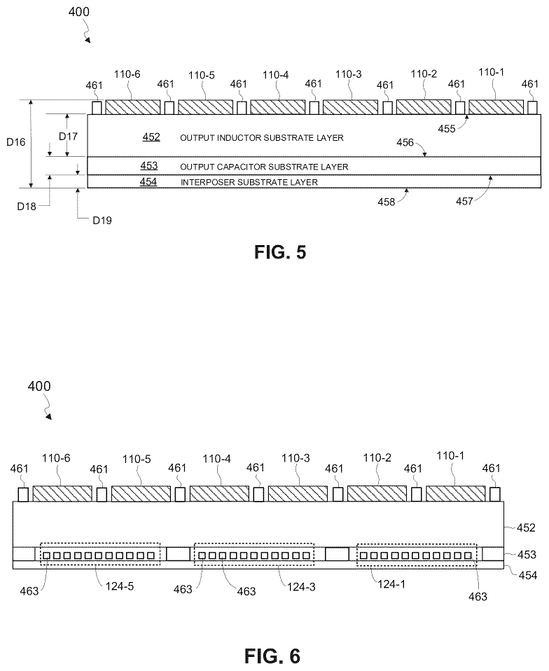

FIG. 5 shows a side view of the power module 400, as viewed in the direction of arrow 462 of FIG. 4. The power module 400 is implemented using a PCB comprising a plurality of substrate layers, namely an output inductor substrate layer 452, an output capacitor substrate layer 453, and an interposer substrate layer 454. Advantageously, the output inductor substrate layer 452 is between the switch blocks 110 and the output capacitor substrate layer 453 to allow a terminal of an output inductor to be efficiently connected to a switch node of a switch block 110.

In the example of FIG. 5, a top surface 455 of the output inductor substrate layer 452 serves as a topmost surface of the PCB on which the switch blocks 110, capacitors 461, and other components of the power module 400 are mounted. A bottom surface 458 of the interposer substrate layer 454 serves as the bottommost surface of the PCB on which pins of the power module 400 are exposed for external connections (e.g., as in the bottom view of FIG. 2). For example, the output voltage nodes 122 and 123 (shown in FIG. 1) may be connected to corresponding pins on the bottom surface 458 of the interposer substrate layer 454. A pin may have a square (e.g., as in a land grid array), round (e.g., as in a ball grid array), or other shape. As can be appreciated, the pinout of the power module 400 depends on implementation details, such as the particular switch blocks 110 employed. The arrangement of the pins on the bottom surface 458 may vary to suit particular applications.

In the example of FIG. 5, the output inductor substrate layer 452 has a bottom surface 456 that directly contacts a top surface of the output capacitor substrate layer 453. The interposer substrate layer 454 has a top surface 457 that directly contacts a bottom surface of the output capacitor substrate layer 453. In one embodiment, the output inductor substrate layer 452 has a thickness D17 of 2.32 mm, the output capacitor substrate layer 453 has a thickness D18 of 0.5 mm, and the interposer substrate layer 454 has a thickness D19 of 0.4 mm. The power module 400 has an overall height D16 of 4 mm measured from the bottom surface 458 of the interposer substrate layer 454 to a topmost surface of a tallest component mounted on the power module 400, which in one embodiment is a switch block 110. The power module 400 may have an overall height of at most 8 mm.

The output inductor substrate layer 452 provides a substrate where the output inductors 120 (shown in FIG. 1) may be embedded within. The output inductors 120 may be embedded within the output inductor substrate layer 452 as explained with reference to FIGS. 2 and 3 except that an end of an output inductor 120 that extends out of the bottom surface now extends to the top surface of the output capacitor substrate layer 453. Electrical connections between and through the substrate layers 452-454 may be made by way of vias and/or nodes in the substrate layers 452-454.

FIG. 6 shows a cross-sectional view of the power module 400 in accordance with an embodiment of the present invention. FIG. 6 is taken at cross-section A-A of FIG. 4. In one embodiment, an output capacitor 124 is implemented by a plurality of discrete (i.e., single, individual component; not part of an integrated circuit), embedded capacitors 463 that are connected in parallel and embedded within the output capacitor substrate layer 453. Note that not all of the embedded capacitors 463 are labeled in FIG. 6 for clarity of illustration. In one embodiment, an embedded capacitor 463 is a size 0201 capacitor. Other discrete capacitor sizes, such as size 0402, may also be used depending on available space in the output capacitor substrate layer 453 and the particular capacitance value of the output capacitor 124. The embedded capacitors 463 may be placed in one or more cavities or other carved out regions within the output capacitor substrate layer 453. In one embodiment, the embedded capacitors 463 are the only discrete components embedded within the output capacitor substrate layer 453. FIG. 6 shows the embedded capacitors 463 of the output capacitors 124-1, 124-3, and 124-5 in cavities embedded within the output capacitor substrate layer 453.

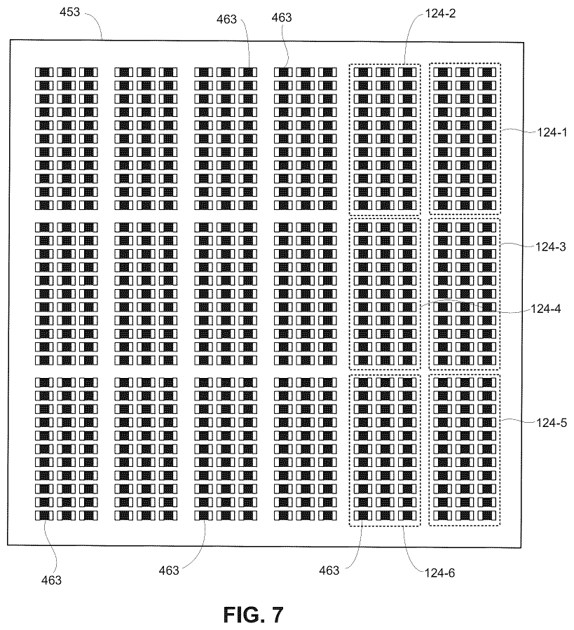

FIG. 7 shows the top view of the output capacitor substrate layer 453 in accordance with an embodiment of the present invention. In the example of FIG. 7, the embedded capacitors 463 are physically arranged in blocks of 33 discrete capacitors, with each block forming an output capacitor 124. The blocks of embedded capacitors 463 are arranged as a 6×3 array. FIG. 7 shows the embedded capacitors 463 that form the output capacitors 124-1, 124-2, 124-3, etc. Only some of the embedded capacitors 463 forming the output capacitors 124 are labeled for clarity of illustration.

Low-profile power modules have been disclosed. While specific embodiments of the present invention have been provided, it is to be understood that these embodiments are for illustration purposes and not limiting. Many additional embodiments will be apparent to persons of ordinary skill in the art reading this disclosure.

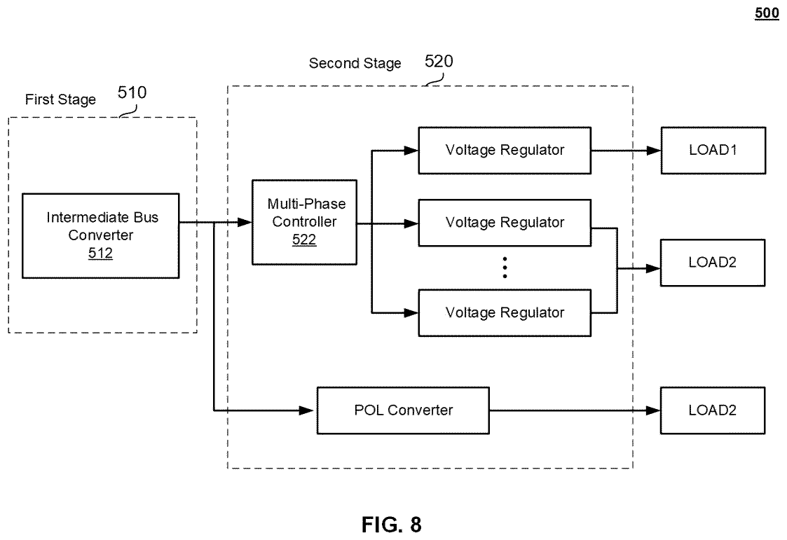

FIG. 8 is a schematic block diagram of a two-stage power supply architecture 500 in accordance with an embodiment of the present invention. In this embodiment, a first stage 510 and a second stage 520 are applied to provide the power to the load. For instance, the first stage 510 includes an intermediate bus converter 512. The intermediate bus converter 512 is configured to receive an input voltage (e.g., 48V) and provide an intermediate voltage (e.g., 12V). In one embodiment, the intermediate bus converter 512 may use a LLC converter, a switched tank converter, a Hybrid switched-capacitor (HSC) converter, or other converter topology.

Depending on the power level of the load, the second stage 520 may utilize a low-dropout regulator (LDO), a buck converter, and/or a multi-phase voltage regulators. For instance, a multi-phase voltage regulator is configured to power the processor and memory that required higher current, while a point-of-load (POL) converter (e.g., a buck converter) or LDO is used to power the fan, and/or other peripheral devices.

In contrast to the one-stage converter, the input voltage of the two-stage converter is reduced, the need for low-duty ratios is also reduced. This reduces losses and improved the efficiency. In addition, the transistors and other electronic components do not need to withstand high voltage, and the cost of the devices could be saved. Furthermore, the sized of the devices could be smaller. Therefore, the proposed two-stage power distribution solution will improve efficiency, scalability, and cost compared to existing solutions.

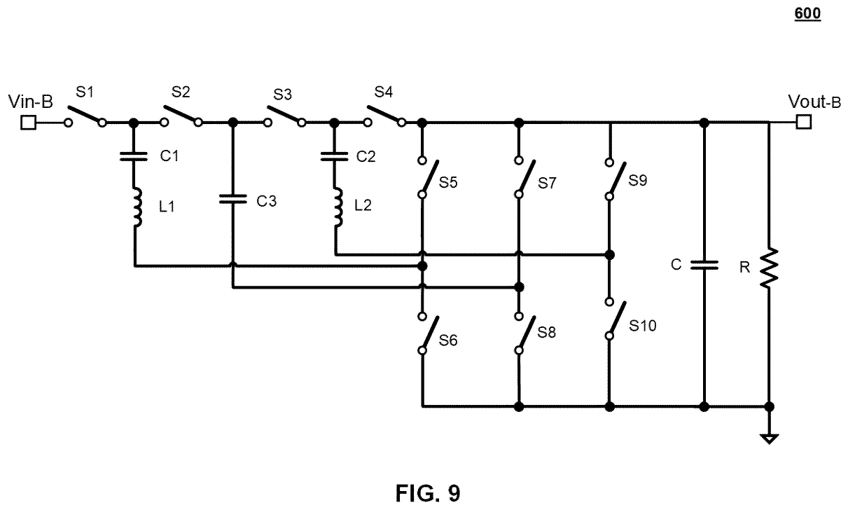

In one embodiment, the intermediate bus converter 512 includes a switched tank converter (STC). FIG. 9 is a schematic circuit diagram of a switched tank converter 600 in accordance with an embodiment of the present invention. As shown in FIG. 9, the switched tank converter 600 includes a plurality of resonant tanks. Each resonant tank includes one resonant inductor (e.g., L1, L2) and one resonant capacitor (e.g., C1, C2). The switched tank converter 600 also includes at least one capacitor (e.g., C1, C3). The switched tank converter 600 further includes a plurality of switches S1, S2, S3, S4, S5, S6, S7, S8, S9 and S10, and an output capacitor C. The switched tank converter 600 receives an input voltage Vin-B from a power supply, and converts the input voltage Vin-B into an output voltage Vout-B to a load R.

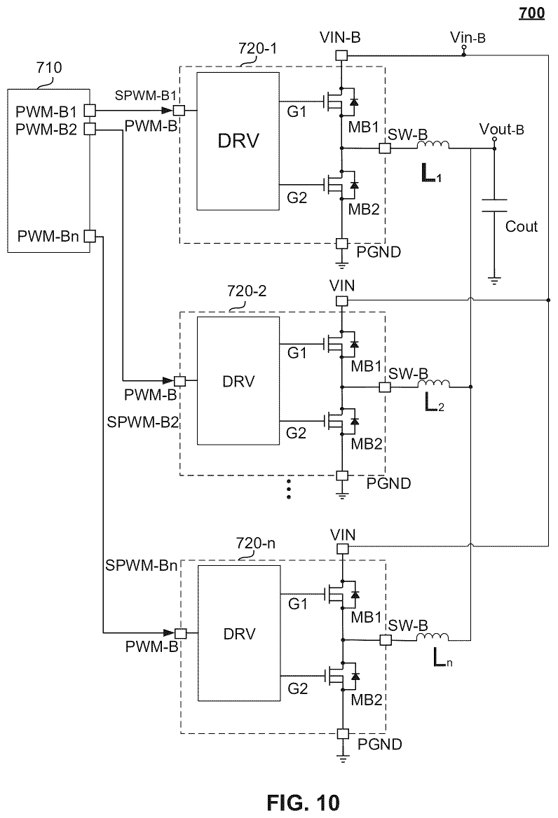

In one embodiment, the second stage includes a multi-phase voltage regulator. FIG. 10 is a schematic block diagram of a multi-phase voltage regulator 700 in accordance with an embodiment of the present invention. The multi-phase voltage regulator 700 includes a multi-phase controller 710, multiple power devices 720-1, 720-2, . . . , 720-n, multiple inductors L₁, L₂, . . . , Lₙ, and an output capacitor Cout, where n is a positive integer greater than 1. Each phase of the voltage regulator includes one power device and inductor. In this embodiment, the voltage regulator is a buck converter. As can be appreciated, the voltage regulator may also be configured as a boost converter or other type of power converter depending on the application. Each phase of the voltage regulator may be connected to provide a multiphase output voltage at the output node Vout-B. The output capacitor Cout is coupled to the output node Vout-B.

In one implementation, the multi-phase controller 710 is an integrated circuit (IC). The multi-phase controller 710 includes multiple pins (e.g., PWM-B1, PWM-B2, . . . , PWM-Bn) configured to provide N phase control signals (e.g., SPWM-B1, SPWM-B2, . . . , SPWM-Bn) respectively to N power devices 720-1, 720-2, . . . , 720-n.

Each power device includes a driving circuit DRV and two switches MB1 and MB2. The high-side switch MB1 is connected to an input voltage VIN. The switches MB1 and MB2 are driven by a driving signal G1 and G2, respectively. In one implementation, each power device is a monolithic IC having a PWM-B pin configured to receive a pulse width modulation (PWM) control signal from the multi-phase controller 710, a VIN-B pin coupled to a voltage source Vin-B to receive an input voltage, a PGND pin coupled to a ground, and a SW-B pin coupled to the output node Vout-B via an inductor for providing the output voltage to a load.

In one implementation, multiple inductors L₁, L₂, . . . , Lₙ are integrated into an inductor module. The inductor module includes one or more magnetic core and windings. In one implementation, the output capacitor Cout is realized by multiple capacitors connected in parallel. In another implementation, the power devices ICs and the inductors are integrated into a power module. In some implementations, the multi-phase controller IC 710, the power devices ICs and the inductor module, the output capacitor are integrated into a power module.

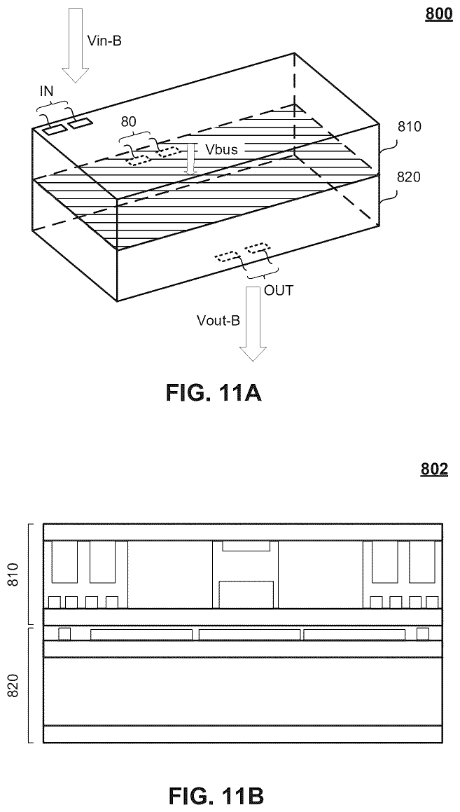

FIG. 11A is a schematic diagram of a power module 800 in accordance with an embodiment of the present invention. The power module 800 includes a first power module 810 and a second power module 820. As shown in FIG. 11A, at least one input pad IN is mounted on the top surface of the first power module 810 and configured to receive an input voltage Vin-B. The first power module 810 further includes at least one power pad 40 mounted on the bottom surface of the first power module 810, and the power pad 40 is configured to provide an intermediate voltage Vbus. The second power module 820 is arranged below the first power module 810. The second power module 820 is configured to receive the intermediate voltage Vbus and configured to provide an output voltage Vout-B. Specifically, at least one signal pad configured to receive the intermediate voltage is mounted on a top surface of the second power module 820, and at least one output pad OUT configured to provide the output voltage OUT is mounted on a bottom surface of the second power module 820.

As shown in FIG. 11A, the power module 800 provides vertical power delivery to a load through the top surface of the first power module 810 to the bottom of the second power module 820. In comparison with the conventional design that all devices are mounted on the plane of one PCB, the size of each PCB of the present invention is smaller since it is stacked vertically. Moreover, since the distance the current flow through the 3D stacking structure is shorter, the power delivery network impedance is reduced. In other words, the power delivery network losses is reduced. Furthermore, the connection losses (e.g., intermediate bus losses) is reduced and thus improves the power density and efficiency.

FIG. 11B is a schematic diagram of a side view of a power module 802 in accordance with an embodiment of the present invention. As shown in FIG. 11B, the first power module 810 is arranged on top of the second power module 820. As can been seen, the ICs and electronic components are arranged between the top surface of the first power module 810 to the bottom of the second power module 820. Thus, the power module 802 provides a flat top surface and a flat bottom surface. In this case, it is easy to connect to other devices, such as the power supply or the load for transmitting and receiving signals and power delivery.

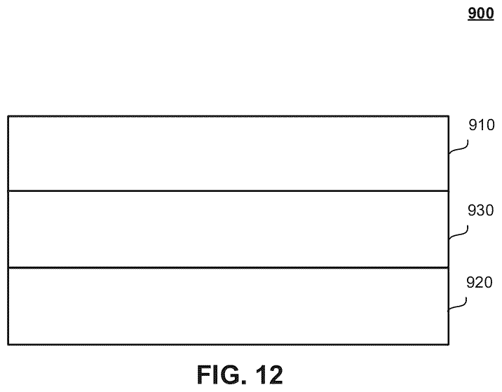

In one embodiment, the power module further includes a heat spreader. FIG. 12 is a schematic diagram of a side view of a power module 900 in accordance with an embodiment of the present invention. As shown in FIG. 12, a heat spreader 930 is arranged between the first power module 910 and the second power module 920. For example, the heat spreader includes a heat sink or a heat exchanger. The heat sink may be a block made by high thermal conductivity material, such as copper. In another example, the heat spreader includes a fan to provide air flow. The heat spreader may also be a heat pipe radiator. The heat pipe radiator includes a container and pipes filled with working fluid.

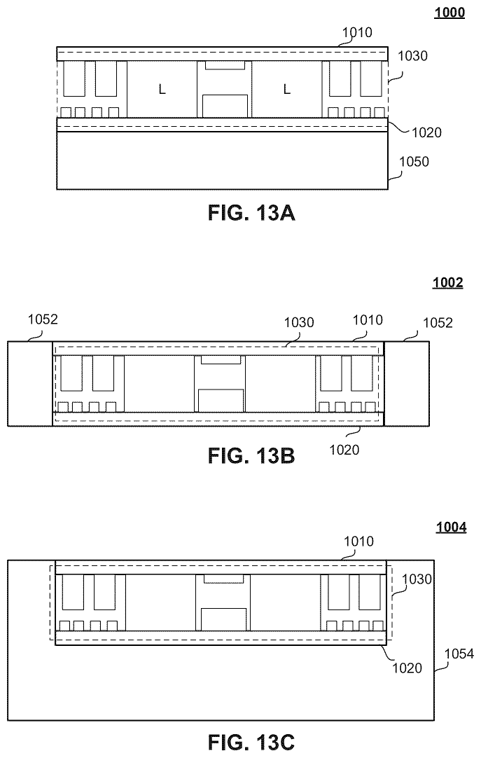

In one embodiment, the first power module includes a switched tank converter. FIG. 13A is a schematic diagram of a side view of a first power module 1000 in accordance with an embodiment of the present invention. As shown in FIG. 13A, the first power module 1000 includes a first printed circuit board (PCB) 1010, a second PCB 1020 arranged below the first PCB, and a switched tank converter circuit 1030. The switched tank converter circuit 1030, including at least one integrated circuit (IC) and a plurality of electronic components, is arranged between the bottom surface of the first PCB 1010 and the top surface of the second PCB 1020. The switched tank converter further includes resistors, inductors, capacitors, transistors, and/or other electronic components. The switched tank converter 1030 is configured to receive an input voltage via at least one input pad mounted on the top surface of the first PCB 1010, and configured to provide an intermediate voltage via at least one signal pad mounted on the bottom surface of the second PCB 1020.

In one implementation, the inductors L are the tallest components in the power module 1000, and thus determine the height of the first power module (i.e., from the top surface of the first PCB 1010 to the bottom surface of the second PCB 1020). The height of the power module 1000 is approximately 3.4 mm.

In this embodiment, the first power module 1000 further includes a heat spreader 1050 arranged below the second PCB 1020. Since the STC structure utilizes inductors instead of a transformer, the inductors L could be arranged between the bottom surface of the first PCB 1010 and the top surface of the second PCB 1020, and thus provide a flat top surface and bottom surface of the first power module 1000 (i.e., STC). As such, the flat surface is beneficial for the heatsink design and thermal management and provides reliable input and output interface. The STC structure also achieves a low profile.

FIG. 13B is a schematic diagram of a side view of a first power module 1002 in accordance with another embodiment of the present invention. As shown in FIG. 13B, the power module is surrounded by the heat spreader 1052. FIG. 13C is a schematic diagram of a side view of a first power module 1004 in accordance with yet another embodiment of the present invention. As shown in FIG. 13C, the power module is embedded in the heat spreader 1054.

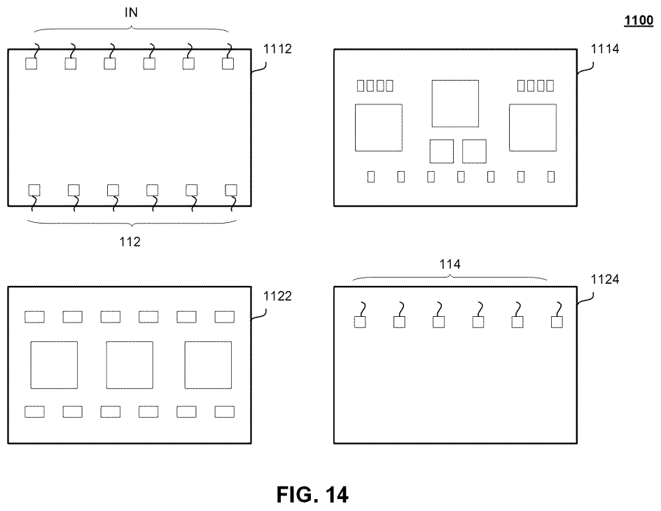

FIG. 14 is a schematic diagram of a plan view a power module 1100 in accordance with an embodiment of the present invention. The power module 1100 includes a first PCB and a second PCB arranged below the first PCB, and a converter circuit disposed on the first PCB and second PCB. As shown in FIG. 14, 1112 is a top view of a first PCB, 1114 is a bottom view of the first PCB, 1122 is a top view of a second PCB, and 1124 is a bottom view of the second PCB. In one embodiment, the converter circuit is a switched tank converter. In one implementation, multiple input pads IN configured to receive an input voltage Vin-B are mounted on the top surface 1112 of first PCB. In some implementations, one or more pads 112 are mounted on the top surface 1112 of first PCB configured to receive or transmit monitor signals, enable signals, control signals and/or ground signals. The switched tank converter circuit, including at least one IC and a multiple electronic components, is arranged on the bottom surface 1114 of the first PCB and the top surface 1122 of the second PCB. The at least one IC has multiple pins coupled to the one or more pads for receiving and transmitting signals. For instance, a STC controller IC, a transistor ICs, a gate driver IC, a rectifier IC, and/or buck converter IC and one or more resistors, inductors, capacitors, transistors, and/or other electronic components are disposed on bottom surface 1114 of the first PCB or the top surface 1122 of the second PCB. Multiple power pads 114 configured to provide an intermediate voltage Vbus are mounted on the bottom surface 1124 of the second PCB. It should be noted that the location, size and shape of the pads, ICs, and the electronic components shown in FIG. 14 is only for illustration purpose. The specific layout of the pads, ICs and electronic components on the two PCBs may be designed according to practical applications.

In one implementation, the length of the first and second PCBs of the first power module is approximately 24 mm and the width of the first and second PCBs is approximately 16.7 mm.

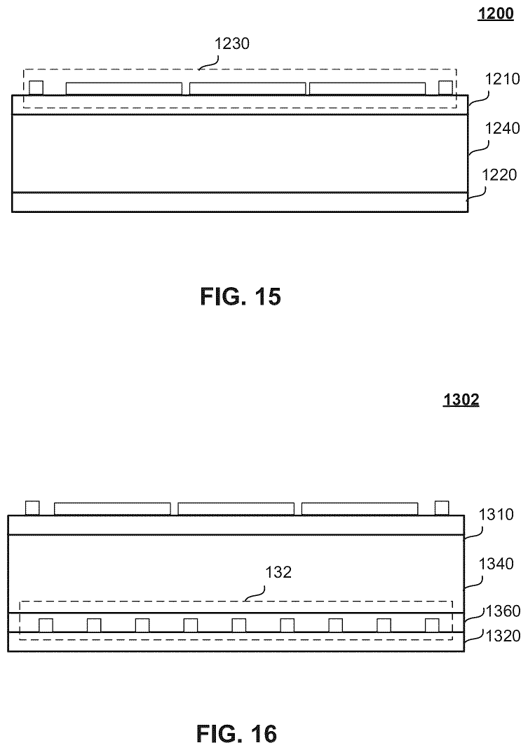

FIG. 15 is a schematic diagram of a side view of a second power module 1200 in accordance with an embodiment of the present invention. As shown in FIG. 15, the second power module 1200 includes a first PCB 1210, a second PCB 1220, a power circuit 1230 and an inductor module 1240. The inductor module 1240 is arranged between the first PCB 1210, and the second PCB. Specifically, a power circuit including at least one IC and a plurality of electronic components is mounted on the top surface of the first PCB 1210.

In one embodiment, the second power module includes a multi-phase voltage regulator. For instance, a multi-phase controller IC and multiple power devices having a driving circuit and two switches are mounted on the top surface of the first PCB 1210. The inductor module is coupled between the multiple power devices and the output pad mounted on the bottom surface of the second PCB 1220. The inductor module includes multiple output inductors, each output inductor is coupled between the corresponding power device and the corresponding output capacitor. The output capacitors are arranged below the inductor module 1240. In one implementation, the output capacitors are mounted on top surface of the second PCB 1220.

In another implementation, the output capacitors are embedded in a substrate layer. FIG. 16 is a schematic diagram of a side view of a second power module 1302 in accordance with another embodiment of the present invention. As shown in FIG. 16, multiple capacitors 132 is embedded in a substrate layer 1360 arranged between the inductor module 1340 and the second PCB 1320.

In some embodiments, the second PCB 1320 is not required. Instead, the inductor module 1240/1340 and/or the substrate layer 1360 may be disposed on a system board of the load. Therefore, the output pads configured to provide an output voltage is disposed on the bottom surface of the inductor module 1240/1340 or disposed on the bottom surface of the substrate layer 1360.

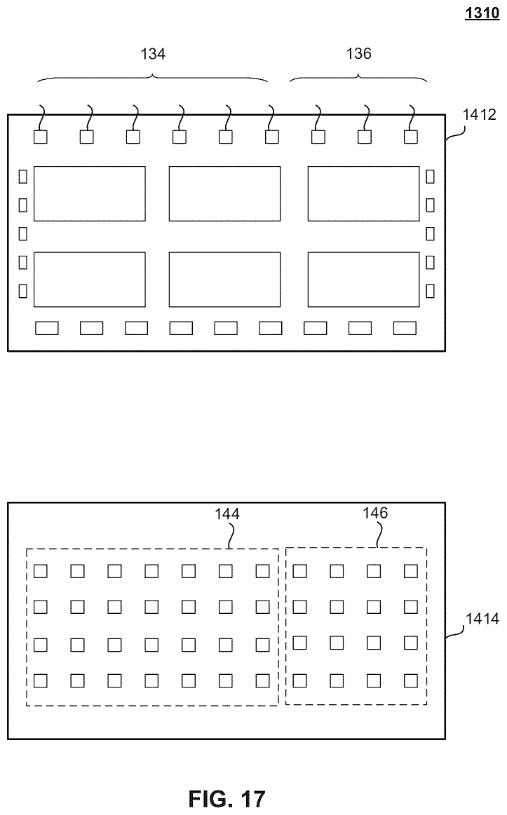

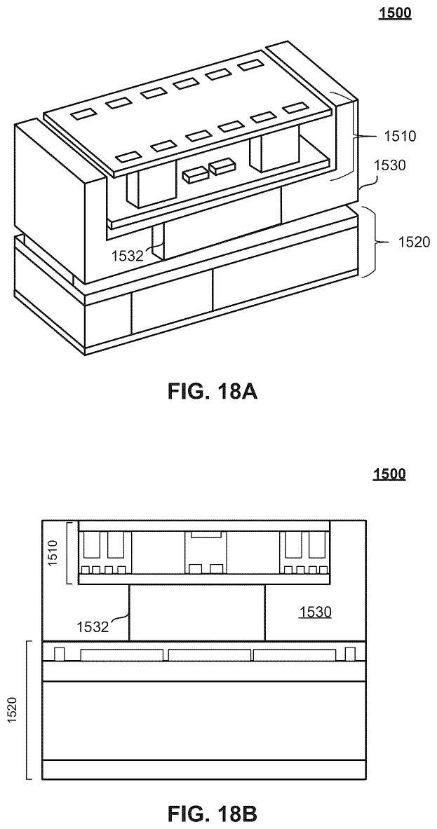

FIG. 17 is a schematic diagram of a plan view a first PCB 1310 of a second power module in accordance with an embodiment of the present invention. As shown in FIG. 17, 1412 is a top view of a first PCB 1310, and 1414 is a bottom view of the first PCB 1310. In one embodiment, the converter circuit is a multi-phase voltage regulator. In one implementation, at least one multiple signal pads 134 configured to receive an intermediate voltage Vbus are mounted on the top surface 1412 of first PCB. In some implementations, one or more pads 136 are mounted on the top surface 1412 of first PCB configured to receive or transmit monitor signals, enable signals, control signals and/or ground signals. A multi-phase controller IC, multiple power ICs and multiple electronic components are arranged on the top surface 1412 of the first PCB. Multiple pads 144 are mounted on the bottom surface 1414 of the first PCB and are configured to provide an output voltage Vout-B. In some implementations, one or more pads 146 configured to receive or transmit monitor signals, enable signals, control signals and/or ground signals. It should be noted that the location, size and shape of the pads, ICs, and the electronic components shown in FIG. 17 is only for illustration purpose. The specific layout of the pads, ICs and electronic components on the two PCBs may be designed according to practical applications.

In one implementation, the length of the first PCB 1310 of the second power module is approximately 29.6 mm and the width of the first and second PCBs is approximately 16.7 mm. The height of the inductor module is approximately 2.3 mm.

FIG. 18A is a schematic diagram of a power module 1500 in accordance with an embodiment of the present invention. FIG. 18B is a schematic diagram of a side view of the power module 1500 in accordance with an embodiment of the present invention. As shown in FIGS. 18A and 18B, the power module 1500 is a sandwich structure. The first power module 1510 is arranged on top of the second power module 1520. The power module 1500 further includes a heat spreader 1530 arranged between the first power module 1510 and the second power module 1520. In one embodiment, the first power module 1510 is embedded in the heat spreader 1530.

In one embodiment, the power module further includes a connector 1532, connected between the first power module 1510 and the second power module 1520, configured to receive and transmit signals. As shown in FIGS. 18A and 18B, the connector 1532 is disposed adjacent to or surrounded by the heat spreader 1530. It is well understood that there may be one or more connectors connected between different layers of PCBs to provide a vertical electrical connection. For instance, the connector may include signal pins made by metal pillars connecting to solder pads on the PCB. The connector may further be realized by metal lines, metal plates, metal contacts, vias and any electrically conductive connectors.

In one implementation, the length of the two-stage power module 1500 is approximately 29.6 mm, the width of the two-stage power module 1500 is approximately 16.7 mm, and the height of the two-stage power module 1500 is approximately 15 mm.

Based on the above, the present invention provides a power module achieves vertical power delivery such that the current travels from top to down through each layer of PCBs. The size of each PCB of the present invention is smaller since it is stacked vertically. Moreover, since the distance the current flow through the 3D stacking structure is shorter, the power delivery network impedance is reduced. Furthermore, the connection losses (e.g., intermediate bus losses) is reduced and thus improves the power density and efficiency. The flat surface is beneficial for the heatsink design and thermal management and provides reliable input and output interface. The sandwich structure also achieves a low profile.

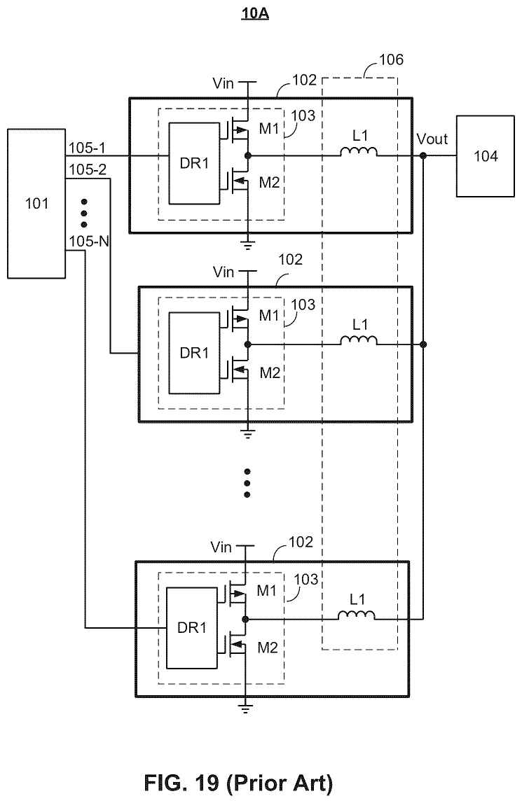

FIG. 19 schematically shows a prior art multi-phase power converter 10A which comprises a controller 101, N power devices 103 and N inductors L1 for supplying power to a load 104, wherein N is an integer, and N>1. Each power device 103 and one inductor L1 represent one power stage, i.e., one phase 102 of the power converter 10A, as shown in FIG. 19. Each power device 103 comprises power switches M1, M2 and a driver DR1 for driving the power switches M1 and M2. The controller 101 provides N phase control signals 105-1˜105-N respectively to N power devices 103 to control the N phases 102 working out of phase, i.e., the inductors L1 sequentially absorb power from the input source and sequentially deliver power to the load 104. It should be noticed that the outputs of all phases as shown in FIG. 19 are connected to work as a multi-phase converter. However, each phase output may be separated to work as multiple independent converters which could have different output voltage levels for different load demands.

The power stages 102 with Buck topology are shown in FIG. 19 for example. Persons of ordinary skill in the art should appreciate that power stages with other topologies, like Boost topology, Buck-Boost topology could also be adopted in a multi-phase power converter.

The inductors L1 could be implemented by one or a few coupled inductors or could be implemented by N single inductors.

When N=2, the multi-phase power converter 10 is used as a dual-phase power converter or two separate single-phase converters.

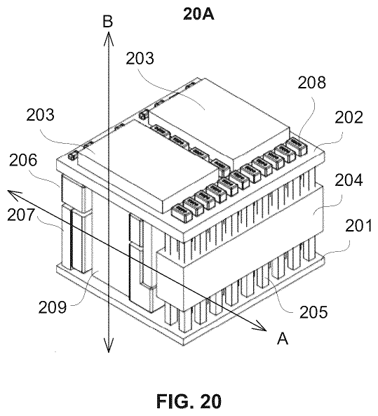

FIG. 20 shows a sandwich structure power supply module 20A for a dual-phase power converter in accordance with an embodiment of the present invention. The power supply module 20A may serve as the power stage 102 of FIG. 19, with N=2. The sandwich structure power supply module 20 comprises: a bottom PCB 201 at the bottom of the sandwich structure power supply module 20A; an inductor pack 206 having two inductors located on the bottom PCB 201, wherein each inductor has a first end and a second end; a top PCB 202 on the top of the inductor pack 206; a connector 204 placed between the bottom PCB 201 and the top PCB 202, wherein the connector 204 has a plurality of metal pillars 205 respectively connecting solder pads on the bottom PCB to solder pads on the top PCB; and two power device chips 203 on the top of the top PCB 202, wherein each one of the power device chips 203 has one or more than one pins connected to the second end of one inductor of the inductor pack 206 via the top PCB 202; wherein each inductor comprises a winding 207 having ends folded to a plane perpendicular to an axis along a length of the winding 207.

In FIG. 20, the power supply module 20A further comprises the discrete components 208 located on the top PCB 202. The discrete components 208 comprise resistors and capacitors of the power converter 10, like the input capacitors at the input terminal to provide pulse current, the filter capacitors and resistors for driver and internal logic circuits power supplies, etc.

In one embodiment, the metal pillars 205 comprises copper pillars for soldering the bottom PCB 201 to the top PCB 202. Persons of ordinary skill in the art should appreciate that the metal pillars 205 could be made of any known material for soldering one PCB to another PCB.

The power supply module 20A is utilized to a mainboard to supply power to the devices on the mainboard. The bottom PCB 201 is soldered to the mainboard to connect the necessary pins of the power supply module 20 to the mainboard. In some embodiments, the bottom PCB 201 could be saved. The connector 204 and the inductor pack 206 are soldered to the mainboard directly.

In the present invention, the inductors and the power device chips are mounted to save the footprint on a PCB integrating the power converter 10 and the devices powered by the power converter 10. Each power device chip 203 integrates the power device 103 in FIG. 19, which comprises the power switches M1, M2, the driver DR1, and further integrates some auxiliary circuits not shown in FIG. 19. The pins of the power device chips 203 are connected to the solder pads on the bottom PCB 201 via the top PCB 202, the inductor pack 206 and the connector 204, to make sure that all the necessary signals could be obtained from the bottom PCB 201. Furthermore, for the signals with large current, like ground reference, the power supply module 20A provides metal layers 209. The metal layers 209 solders the top PCB 202 to the bottom PCB 201. The metal layer 209 coats part of a magnetic core of the inductor pack 206. The location of the metal layer 209 is determined by the location of ground reference pins of the power device chips 203. In the example of FIG. 20, since the metal layers 209 are placed at the side of the inductor pack 206, the ends of the metal layers 209 are bent to produce tabs close to the ground reference pins of the power device chips 203, so that to carry high current in the horizontal direction only through metal tabs instead of PCB traces which lowers conduction loss and improve efficiency.

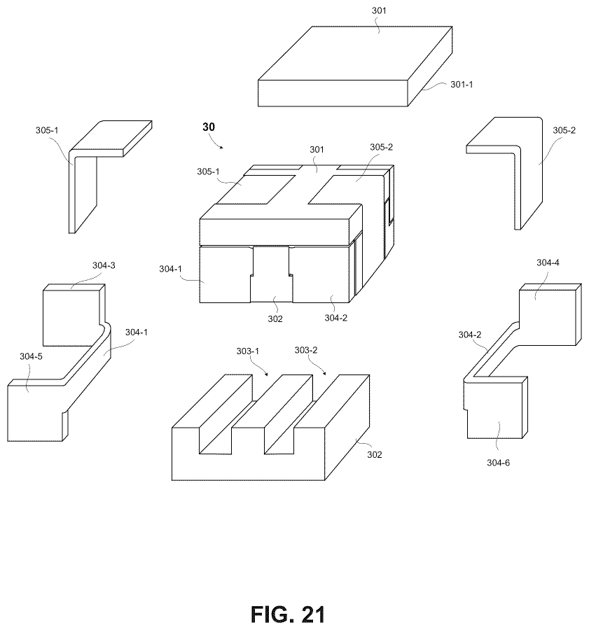

FIG. 21 shows the disassembled view of an inductor pack 30 in accordance with an embodiment of the present invention. The inductor pack 30 may be served as the inductor pack 206 in FIG. 20. As shown in FIG. 21, the inductor pack 30 comprises: a magnetic core having a first magnetic core part 301 and a second magnetic core part 302, wherein the first magnetic core part 301 and the second magnetic core part 302 are assembled to have two passageways 303-1 and 303-2 at a planer where the first magnetic core part 301 and the second magnetic core part 302 are aligned; and two windings 304-1 and 304-2 respectively passing through two passageways 303-1 and 303-2 between the first magnetic core part 301 and the second magnetic core part 302.

In the embodiment of FIG. 21, the passageways 303-1 and 303-2 have a depth along an axis A parallel to the bottom PCB 201 and the top PCB 202 as shown in FIG. 20.

In the embodiment of FIG. 21, the winding 304-1 has a first end 304-3 bent 90 degrees to cover a surface of the magnetic core and extended to the top PCB 202 to be soldered to the top PCB 202, and a second end 304-5 bent 90 degrees to cover a surface of the magnetic core and extended to the bottom PCB 201 to be soldered to the bottom PCB 201, and wherein the first end 304-3 and the second end 304-5 of the winding 304-1 are extended at a plane perpendicular to an axis along the depth of the passageways 303-1 and 303-2 of the magnetic core. Similarly, the winding 304-2 has a first end 304-4 bent 90 degrees to cover a surface of the magnetic core and extended to the top PCB 202 to be soldered to the top PCB 202, and a second end 304-6 bent 90 degrees to cover a surface of the magnetic core and extended to the bottom PCB 201 to be soldered to the bottom PCB 201, and wherein the first end 304-4 and the second end 304-6 of the winding 304-2 are extended at a plane perpendicular to an axis along the depth of the passageways 303-1 and 303-2 of the magnetic core.

In the embodiment of FIG. 21, the magnetic core has a first magnetic core part 301 and a second magnetic core part 302 which are asymmetrical, wherein the first magnetic core part 301 is in a planar shape and the second magnetic core part 302 has two trenches, and wherein each of the passageways 303-1, 303-2 is respectively formed by a trench of the second magnetic core 302 and a surface 301-1 of the first magnetic core 301.

In the embodiment of FIG. 21, the metal layers 305-1 and 305-2 have an L-shape. The metal layers 305-1 and 305-2 are configured to solder the top PCB 202 to the bottom PCB 201. The ends of the metal layers 305-1 and 305-2 for soldering the top PCB 202 are bent 90 degrees and extended to produce tabs to be soldered to the ground reference pins of the power device chips 203 via the top PCB 202 with minimized PCB trace impedance inside the top PCB.

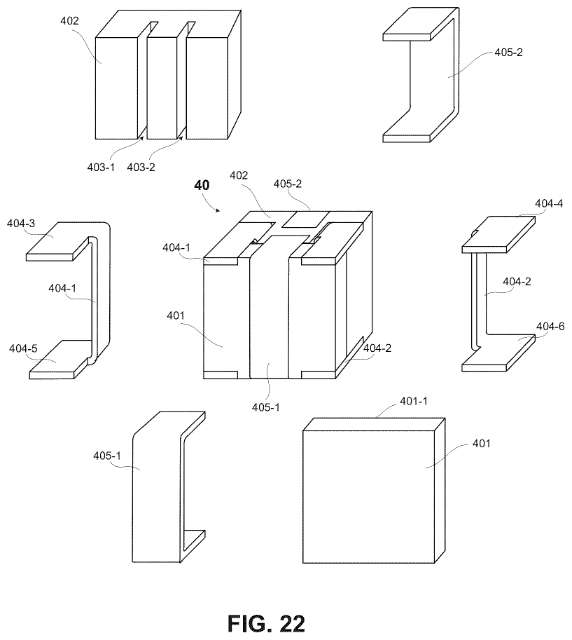

FIG. 22 shows the disassembled view of an inductor pack 40 in accordance with an embodiment of the present invention. The inductor pack 40 may be served as the inductor pack 206 in FIG. 20. As shown in FIG. 22, the inductor pack 40 comprises: a magnetic core having a first magnetic core part 401 and a second magnetic core part 402, wherein the first magnetic core part 401 and the second magnetic core part 402 are assembled to have two passageways 403-1 and 403-2 at a planer where the first magnetic core part 401 and the second magnetic core part 402 are aligned; and two windings 404-1 and 404-2 respectively passing through two passageways 403-1 and 403-2 between the first magnetic core part 401 and the second magnetic core part 402.

In the embodiment of FIG. 22, the passageways 403-1 and 403-2 have a depth along an axis B perpendicular to the bottom PCB 201 and the top PCB 202 if adopted by the power supply module 20A in FIG. 20.

In the embodiment of FIG. 22, the winding 404-1 has a first end 404-3 bent 90 degrees to cover a surface of the magnetic core and extended along a surface of the top PCB 202 to be soldered to the top PCB 202, and a second end 404-5 bent 90 degrees to cover a surface of the magnetic core and extended along a surface of the bottom PCB 201 to be soldered to the bottom PCB 201, and wherein the first end 404-3 and the second end 404-5 of the winding 404-1 are extended at a plane perpendicular to an axis along the depth of the passageways 403-1 and 403-2 of the magnetic core. Similarly, the winding 404-2 has a first end 404-4 bent 90 degrees to cover a surface of the magnetic core and extended along a surface of the top PCB 202 to be soldered to the top PCB 202, and a second end 404-6 bent 90 degrees to cover a surface of the magnetic core and extended along a surface of the bottom PCB 201 to be soldered to the bottom PCB 201, and wherein the first end 404-4 and the second end 404-6 of the winding 404-2 are extended at a plane perpendicular to an axis along the depth of the passageways 403-1 and 403-2 of the magnetic core.

In some embodiments, the second end 404-5 of the windings 404-1, and the second end 404-6 of the windings 404-2 are not bent. Whether the second ends of the winding are bent or not, and the locations, shapes of the second ends of the windings, are determined by the locations of the associated solder pads on the bottom PCB of the power supply module, or the associated solder pads on the mainboard if the bottom PCB is saved.

In the embodiment of FIG. 22, the magnetic core has a first magnetic core part 401 and a second magnetic core part 402 which are asymmetrical, wherein the first magnetic core part 401 is in a planar shape and the second magnetic core part 402 has two trenches, and wherein each of the passageways 403-1, 403-2 is respectively formed by a trench of the second magnetic core 402 and a surface 401-1 of the first magnetic core 401.

In the embodiment of FIG. 22, the metal layers 405-1 and 405-2 have a C shape. The metal layers 405-1 and 405-2 are configured to solder the top PCB 202 to the bottom PCB 201. The ends of the metal layers 405-1 and 405-2 for soldering the bottom PCB 201 are bent 90 degrees and extended to produce tabs to be soldered to the bottom PCB 201 with minimized PCB trace impedance inside the bottom PCB 201. Also, the ends of the metal layers 405-1 and 405-2 for soldering the top PCB 202 are bent 90 degrees and extended to produce tabs to be soldered to the ground reference pins of the power device chips 203 via the top PCB 202 with minimized PCB trace impedance inside the top PCB 202.

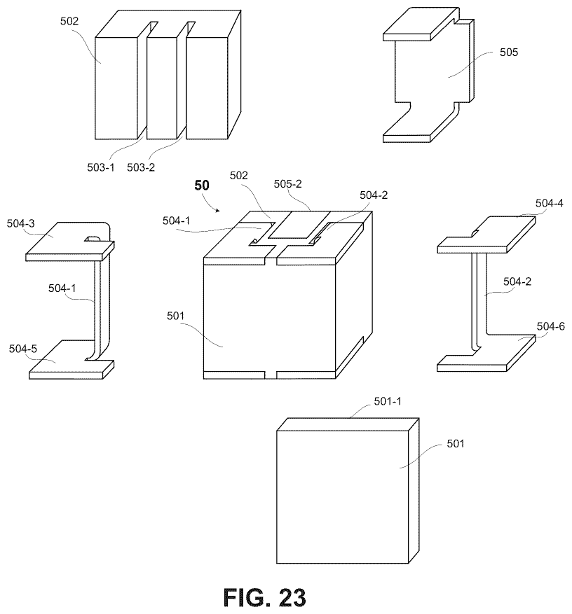

FIG. 23 shows the disassembled view of an inductor pack 50 in accordance with an embodiment of the present invention. The inductor pack 50 may be served as the inductor pack 206 in FIG. 20. As shown in FIG. 23, the inductor pack 50 comprises: a magnetic core having a first magnetic core part 501 and a second magnetic core part 502, wherein the first magnetic core part 501 and the second magnetic core part 502 are assembled to have two passageways 503-1 and 503-2 at a planer where the first magnetic core part 501 and the second magnetic core part 502 are aligned; and two windings 504-1 and 504-2 respectively passing through two passageways 503-1 and 503-2 between the first magnetic core part 501 and the second magnetic core part 502.

In the embodiment of FIG. 23, the passageways 503-1 and 503-2 have a depth along an axis B perpendicular to the bottom PCB 201 and the top PCB 202 if adopted by the power supply module 20A in FIG. 20.

In the embodiment of FIG. 23, the metal layer 505 has a C shape. The metal layer 505 is configured to solder the top PCB 202 to the bottom PCB 201. The end of the metal layer 505 for soldering the bottom PCB 201 are bent 90 degrees and extended to produce tabs to be soldered to the bottom PCB 201 with minimized PCB trace impedance inside the bottom PCB 201. Also, the end of the metal layer 505 for soldering the top PCB 202 are bent 90 degrees and extended to produce tabs to be soldered to the ground reference pins of the power device chips 203 via the top PCB 202 with minimized PCB trace impedance inside the top PCB 202. In the example of FIG. 23, the middle part of the metal layer 505 are extended to both sides to lower the impedance of the metal layer 505.

Compared with the inductor pack 40 in FIG. 22, the inductor pack 50 in FIG. 23 has one metal layer 505 for soldering the ground pins from the top PCB 202 to the bottom PCB 201. Since the area for another ground metal layer as in FIG. 22 is saved, the ends of the windings in the embodiment of FIG. 23 extend to larger areas at the top and the bottom of the inductor pack 50, which makes the power device chips 203 have more flexibility to configure pins.

The magnetic core having a first magnetic core part 501 and a second magnetic core part 502 in the embodiment of FIG. 23 is similar to the magnetic core in the embodiment of FIG. 22, and is not described here for brevity.

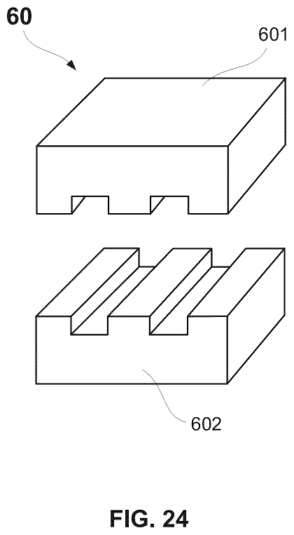

FIG. 24 shows a magnetic core 60 in accordance with an embodiment of the present invention. In FIG. 24, the magnetic core 60 comprises a first magnetic core part 601 and a second magnetic core part 602 which are symmetrical, wherein each one of the magnetic core parts has two trenches. When the magnetic core 60 is adopted by the inductor pack 30 in FIG. 21, the inductor pack 40 in FIG. 22, or the inductor pack 50 in FIG. 23, each passageway for passing a winding is formed by a trench of the first magnetic core part 601 and a trench of the second magnetic core part 602.

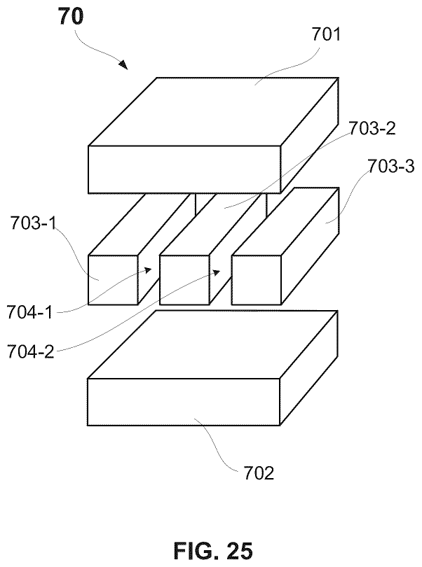

FIG. 25 shows a magnetic core 70 in accordance with an embodiment of the present invention. In FIG. 25, the magnetic core 70 comprises a first magnetic core part 701, a second magnetic core part 702 and third magnetic core parts 703-1˜703-3. The first magnetic core part 701, the second magnetic core part 702 and the third magnetic core parts 703-1 and 703-2 forms a passageway 704-1. The first magnetic core part 701, the second magnetic core part 702 and the third magnetic core parts 703-2 and 703-3 forms a passageway 704-2. More passageways could be formed when there are more third magnetic core parts. The first magnetic core part 701, the second magnetic core part 702 and the third magnetic core parts 703-1˜703-3 could be made of different materials to provide a more flexible inductance-current curve.

In some embodiments of the present invention, the magnetic core parts of the magnetic core may be made of the same material, but have different geometries and/or percent composition to meet an inductance-current requirement of a target inductance profile, e.g., high inductance at low currents and low inductance at high currents. High inductance at low currents allows for higher efficiency, while low inductance at high currents allows for better transient response. In some embodiments, the magnetic core parts of the magnetic core may be made of different materials, like ferrite, iron powder, and any other suitable magnetic material to obtain a target inductance profile.

The inductor pack 30 in FIG. 21, the inductor pack 40 in FIG. 22 and the inductor pack 50 in FIG. 23 show magnetic cores with two windings respectively passing through two passageways of the magnetic cores for illustration. Persons of ordinary skill in the art should appreciate that the magnetic cores of the present invention could have any number of passageways and the corresponding windings according to the application requirement, like, one, or more than two.

In some embodiments, a gap may exist between the magnetic core parts of the magnetic core to form a coupled inductor. In some embodiments, independent inductors are formed with no gap between the magnetic core parts.

In the present invention, to make the inductor packs have planar surfaces, the windings and the metal layers that cover the surfaces of the magnetic cores are damascened into the magnetic core surfaces as shown in FIGS. 21 and 22.

The power supply module 20A may be employed in various applications including graphics processing unit (GPU), central processing unit (CPU), data center application-specific integrated circuit (ASIC), etc. applications. During fast load transients, a sufficient number of output capacitors is required to limit output voltage undershoot and overshoot. However, output capacitors consume a lot of board space and decrease circuit density. This problem is especially troublesome in applications with a fixed board form factor, where the board space required by the output capacitors reduces the number of power converters available on the power supply module, thereby limiting the power that can be delivered to GPUs, CPUs, etc.

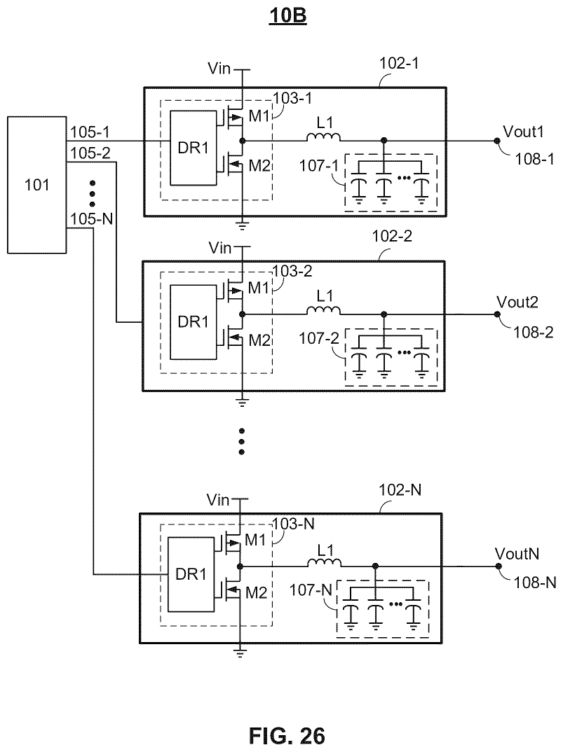

FIG. 26 schematically shows a multi-phase power converter 10B in accordance with another embodiment of the present invention. Compared with the power converter 10A of FIG. 19, each phase 102 (i.e., 102-1, 102-2, . . . , 102-N) of the power converter 10B further comprises an output capacitor 107 (i.e., 107-1, 107-2, . . . , 107-N). In one embodiment, an output capacitor 107 comprises a plurality of discrete capacitors that are connected in parallel. The power devices 103 are coupled to an input voltage Vin. The power switch M1 of each power device 103 is coupled to an input voltage Vin, and the power switch M2 of each power device 103 is coupled to a ground GND. The controller 101 provides N phase control signals 105 (i.e., 105-1, 105-2, . . . , 105-N) respectively to the N power devices 103 (i.e., 103-1, 103-2, . . . , 103-N) to control the N phases 102 working out of phase, which were previously explained with reference to the power converter 10A of FIG. 19. In the example of FIG. 26, each phase 102 has a corresponding output voltage node 108 (i.e., 108-1, 108-2, . . . , 108-N) to provide an output voltage (i.e., Vout1, Vout2, . . . , VoutN). In one embodiment, all the output voltage nodes 108 are connected together to supply the load 104. In another embodiment, the output voltage nodes 108 may not be connected together, and the N phases 102 work as N separate single-phase converters.

As shown in FIG. 26, each output capacitor 107 is connected to each output voltage node 108 correspondingly. In the example of FIG. 26, an output capacitor 107-1 has a first end that is connected to the output voltage node 108-1 and a second end that is connected to the ground GND. Similarly, an output capacitor 107-2 has a first end that is connected to the output voltage node 108-2 and a second end that is connected to the ground GND, etc. Other capacitors (e.g., input capacitors, supply capacitors) and other components not necessary to the understanding of the invention are not shown in FIG. 26 for clarity of illustration.

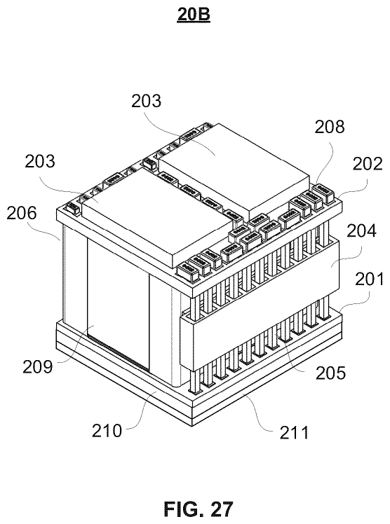

FIG. 27 shows a sandwich structure power supply module 20B with output capacitors embedded for a dual-phase power converter in accordance with an embodiment of the present invention. The power supply module 20B may serve as the power stages 102 of FIG. 26, with N=2. As shown in FIG. 27, the power supply module 20B comprises the inductor pack 206 having two inductors, wherein each inductor has a first end and a second end; the top PCB 202 on the top of the inductor pack 206; the bottom PCB 201 under the inductor pack 206; the connector 204 placed between the bottom PCB 201 and the top PCB 202 for connecting the solder pads on the bottom PCB to the solder pads on the top PCB; the discrete components 208 and the two power device chips 203 integrating the power devices 103 on the top of the top PCB 202, wherein each one of the power device chips 203 has one or more pins connected to the second end of one inductor of the inductor pack 206 via the top PCB 202. In some embodiments, the detailed structure of the inductor pack 206 may be as shown in FIGS. 22-25, and persons of ordinary skill in the art should understand that shapes of the magnetic core and the windings of the inductor pack 206 are not limited by the examples shown in FIGS. 22-25.

Compared with the power supply module 20A of FIG. 20, the output capacitors 107 are further integrated in the power supply module 20B shown in FIG. 27, and are arranged below the inductor pack 206. In the example of FIG. 27, the power supply module 20B further comprises an output capacitor substrate layer 210 disposed below the bottom PCB 201, and the output capacitors 107 are embedded within the output capacitor substrate layer 210. In some embodiments, the bottom PCB 201 may be omitted, and the connector 204 and the inductor pack 206 are soldered to the output capacitor substrate layer 210 directly.

In the example of FIG. 27, the power supply module 20B further comprises an interposer substrate layer 211 disposed below and touches the output capacitor substrate layer 210. The power supply module 20B is utilized to a mainboard of the load 104 (e.g., a CPU, a GPU, or an ASIC, etc.) to supply power to the devices on the mainboard. The interposer substrate layer 211 is soldered to the mainboard to connect the necessary pins of the power supply module 20B to the mainboard. In some embodiments, the interposer substrate layer 211 may not be required, in which case the necessary pins of the power supply module 20B are exposed on a bottom surface of the output capacitor substrate layer 210, and the output capacitor substrate layer 210 is soldered to the mainboard directly.

In the embodiment of FIG. 27, the pins of the power device chips 203 are connected to the solder pads on the interposer substrate layer 211 via the top PCB 202, the inductor pack 206, the connector 204, and the output capacitor substrate layer 210 to make sure that all the necessary signals could be obtained from the interposer substrate layer 211. Furthermore, the power supply module 20B provides the metal layers 209 for soldering ground reference pins and/or power pins (i.e., pins receiving the input voltage Vin) of the power device chips 203 via the top PCB 202 directly to the bottom PCB 201 or to the output capacitor substrate layer 210, so that to carry high current in the horizontal direction only through metal tabs instead of PCB traces which lowers conduction loss and improve efficiency.

In the example of FIG. 27, the connector 204 has a plurality of metal pillars 205 respectively connecting the solder pads on the bottom PCB to the solder pads on the top PCB. As can be appreciated, the connector 204 may also be implemented in other shapes, e.g., the connector 204 may be integrated together with the inductor pack 206. In one embodiment, the metal pillars 205 comprises copper pillars. Persons of ordinary skill in the art should appreciate that the metal pillars 205 could be made of any known material for soldering one PCB to another PCB.

In embodiments of the present invention, to conserve board space, the output capacitors 107 are implemented by a plurality of parallel-connected discrete capacitors embedded within the output capacitor layer 210.

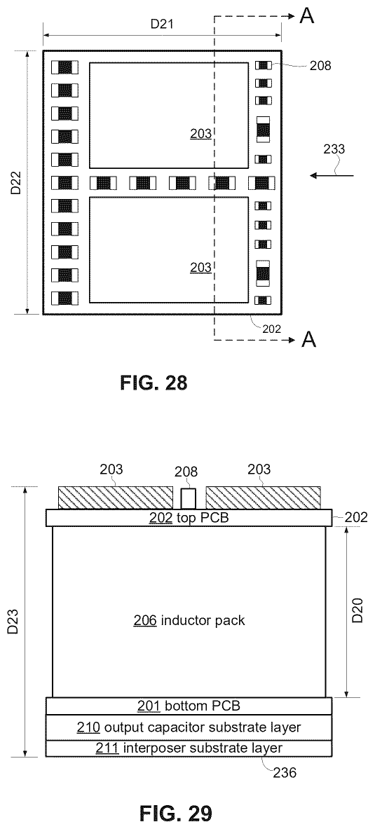

FIG. 28 shows a top view of the power supply module 20B of FIG. 27 in accordance with an embodiment of the present invention. As shown in FIG. 28, the power device chips 203 and the discrete components 208 are mounted on a topmost surface of the top PCB 202. In one embodiment, the top PCB 202 has a width D21 of about 9 mm and a length D22 of about 10 mm.

FIG. 29 shows a side view of the power supply module 20B of FIG. 27 in accordance with an embodiment of the present invention, as viewed in the direction of an arrow 233 of FIG. 28. As shown in FIG. 29, a bottom surface 236 of the interposer substrate layer 211 serves as the bottommost surface of the power supply module 20B on which pins of the power supply module 20B are exposed for external connections. In one embodiment, a height D20 of the inductor pack 206 measured from a bottom surface of the inductor pack 206 to a top surface of the inductor pack 206 is 5.8 mm and in a range of 2 mm˜8 mm, and an inductance of each inductor of the inductor pack 206 is in a range of 40 nH˜150 nH, typically 100 nH. As can be appreciated, the height of the inductor pack 206 and the inductance of each inductor of the inductor pack 206 depend on the particulars of the application. In one embodiment, a power device chip 203 is the tallest component on the top PCB 202, and a height D23 from the bottom surface of the top PCB 202 to the topmost surface of a power device 203 is 10 mm and in a range of 4 mm-12 mm.

In the example of FIG. 29, the bottom PCB 201 has a bottom surface that directly contacts a top surface of the output capacitor layer 210. The interposer substrate layer 211 has a top surface that directly contacts a bottom surface of the output capacitor layer 210. As mentioned before, in some embodiments, the bottom PCB 201 could be omitted.

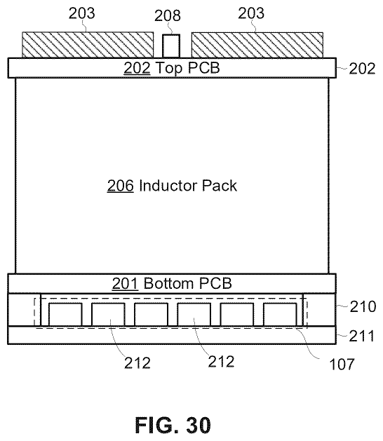

FIG. 30 shows a cross-sectional view of the power supply module 20B of FIG. 27 in accordance with an embodiment of the present invention. FIG. 30 is taken at cross-section A-A of FIG. 28. In one embodiment, the output capacitors 107 are implemented by a plurality of discrete (i.e., single, individual component; not part of an integrated circuit), embedded capacitors 212 that are connected in parallel and embedded within the output capacitor layer 210. Note that not all of the embedded capacitors 212 are labeled in FIG. 30 for clarity of illustration. In one embodiment, an embedded capacitor 212 is a size 0201 capacitor. Other discrete capacitor sizes, such as size 0402, may also be used depending on available space in the output capacitor substrate layer 210 and the particular capacitance values of the output capacitors 107. The embedded capacitors 212 may be placed in one or more cavities or other carved out regions within the output capacitor layer 210. In one embodiment, the embedded capacitors 210 are the only discrete components embedded within the output capacitor substrate layer 210. FIG. 30 shows the embedded capacitors 212 of the output capacitors 107-1 and 107-2 in cavities embedded within the output capacitor layer 210.

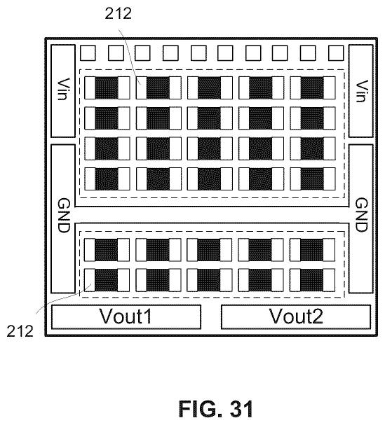

FIG. 31 shows a top view of the output capacitor layer 210 in accordance with an embodiment of the present invention. In the example of FIG. 31, the embedded capacitors 212 are physically arranged in the cavities within the output capacitor layer 210 (FIG. 31, boxes drawn in dashed lines). FIG. 31 shows the embedded capacitors 212 that form the output capacitors 107-1 and 107-2. FIG. 31 further shows solder pads (FIG. 31, boxes drawn in solid lines) for the input voltage Vin, the output voltages Vout1 and Vout2, the ground GND and other signals on the top surface of the output capacitor layer 210. As can be appreciated, the arrangement of the cavities within the output capacitor layer 210 and the solder pads on the output capacitor layer 210 may vary to suit particular applications.

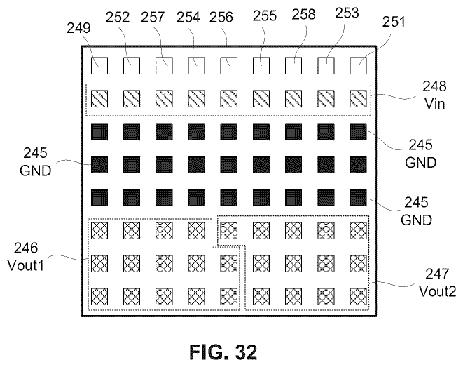

FIG. 32 shows a bottom view of the power supply module 20B of FIG. 27 in accordance with an embodiment of the present invention. In the example of FIG. 32, a bottom side of the interposer layer 211 serves as a bottom side of the power supply module 20B. The bottom side of the interposer layer 211 has a plurality of pins that connect nodes of the power supply module 20B to components that are external to the power supply module 20B, such as a PWM controller, etc. A pin may be a pad or other means for electrically connecting nodes and components. A pin may have a square (e.g., as in a land grid array), round (e.g., as in a ball grid array), or other shape. The power supply module 20B may be employed as part of a power supply (not shown). The pins of the power supply module 20B may be connected to corresponding sockets on a substrate of the power supply.

In the example of FIG. 32, each pin of the power supply module 20B has a square shape, e.g., 0.45 mm×0.45 mm square. The pins that are connected to the ground GND, some of which are labeled as “245”, are depicted in black. Not all of the pins for the ground GND are labeled for clarity of illustration. The pins that are connected to the output voltage node 108-1 to provide a first output voltage Vout1 are collectively labeled as “246”, and the pins that are connected to the output voltage node 108-2 to provide a second output voltage Vout2 are collectively labeled as “247”. In another example, the pins for the first output voltage Vout1 and for the second output voltage Vout2 are coupled together. The pins that are connected to receive the input voltage Vin are collectively labeled as “248”. A pin 249 is connected to receive a PWM signal to the power device chip 203-1; a pin 251 is connected to receive a PWM signal to the power device chip 203-2; a pin 252 is connected to provide a current monitor signal from the power device chip 203-1; a pin 253 is connected to provide a current monitor signal from the power device chip 203-2; a pin 254 is connected to provide a temperature monitoring signal from the power device chip 203-1; a pin 255 is connected to provide a temperature monitoring signal from the power device chip 203-2; a pin 256 is connected to receive a VCC supply voltage; and a pin 257 is connected to receive an enable signal to the power device chip 203-1, and a pin 258 is connected to receive an enable signal to the power device chip 203-2.

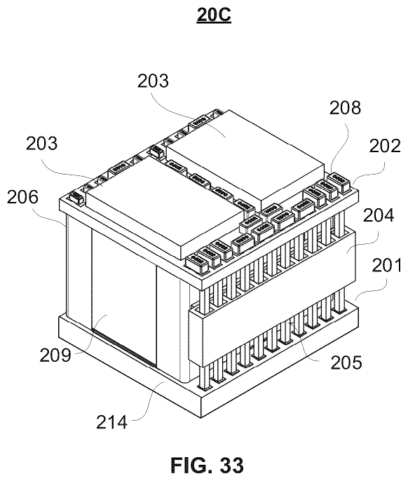

FIG. 33 shows a sandwich structure power supply module 20C with output capacitors embedded for a dual-phase power converter in accordance with another embodiment of the present invention. In the example of FIG. 33, the inductor pack 206, the metal layers 209, and the connector 204 are disposed between the top PCB 202 and an integrated bottom substrate layer 214. The output capacitors 107 are embedded within the integrated bottom substrate layer 214, and the pins of the power supply module 20C are exposed on a bottom surface of the integrated bottom substrate layer 214. In another embodiment, the bottom PCB 201, the output capacitor substrate layer 210, and the interposer layer 211 of the power supply module 20C are molded together to form the integrated bottom substrate layer 214.

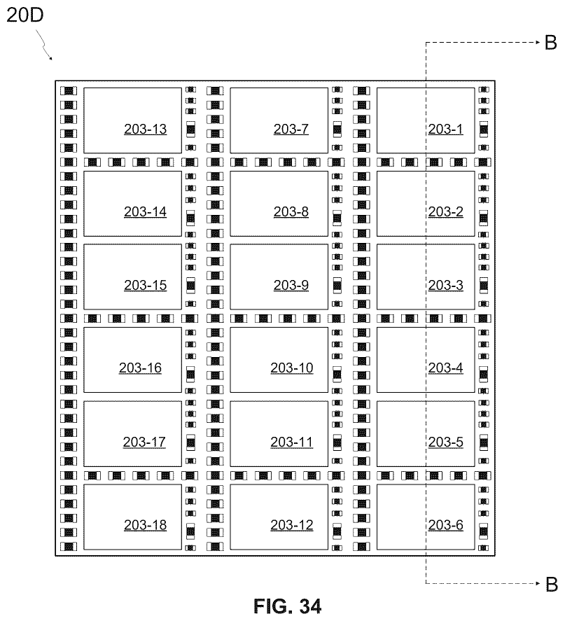

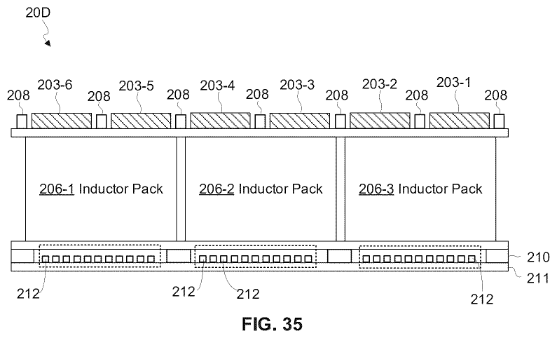

FIG. 34 schematically shows a top view of a power supply module 20D in accordance with another embodiment of the present invention. In the example of FIG. 35, the power supply module 20D has 18 phases. The top view of FIG. 34 shows a topmost surface of the top PCB 202 of the power supply module 20D where the power device chips 203 (i.e., 203-1, 203-2, . . . , 203-18), the discrete components 208, and other components (not shown) of the power supply module 20D are mounted. Each of the power device chips 203 of the power supply module 20D may be employed in a power device 103 as described in connection with FIG. 19. The power supply module 20D has 18 power device chips 203 for illustration purposes only. Generally speaking, the number of power device chips on a power supply module, and thus the number of phases of the power supply module, depends on the particulars of the application. As can be appreciated, the specific layout of the components of the power supply module 20D may also be configured to suit application details.

FIG. 35 schematically shows a cross-sectional view of the power supply module 20D of FIG. 34 in accordance with an embodiment of the present invention. FIG. 35 is taken at cross-section B-B of FIG. 34. The power supply module 20D comprises a plurality of inductor packs 206, each inductor pack 206 integrates two inductors. In the example of FIG. 35, the power supply module 20D comprises 9 inductor packs 206, and the cross-sectional view of FIG. 35 shows the inductor packs 206-1, 206-2, and 206-3. As can be appreciated, the number of the inductor packs 206 depends on the particulars of the application, and in some other embodiments, each inductor pack 206 may also comprise more than two inductors.

The power supply module 20D further comprises the output capacitors 107 for the 18 phases which are implemented by the embedded capacitors 212. In the example of FIG. 35, the embedded capacitors 212 are placed in a plurality of cavities or other carved out regions within the output capacitor layer 210. Structures and connection of the other parts of the power supply module 20D (e.g., the top PCB 202, the bottom PCB 201, and the connectors 204, etc.) are similar to which of the power supply module 20B, and are not described here for brevity. In another embodiment, the bottom PCB 201, the output capacitor layer 210, and the interposer substrate layer 211 are replaced by the integrated bottom substrate layer 214, and the output capacitors 107 are embedded within the integrated bottom substrate layer 214.

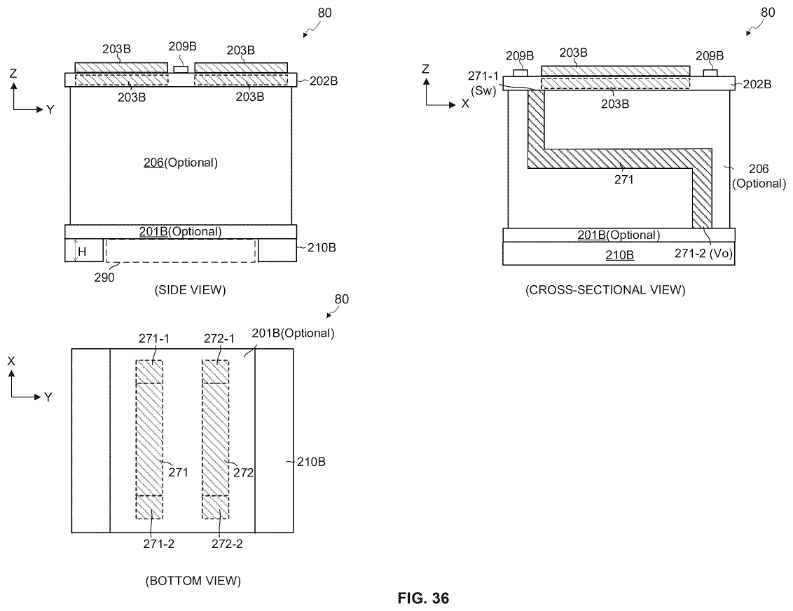

As mentioned before, in some embodiments, the interposer substrate layer 211 may not be required. FIG. 36 schematically shows, from the upper left hand corner in clock-wise direction, a side view, a cross-sectional view, and a bottom view of a power supply module 80 in accordance with an embodiment of the present invention. In the embodiment of FIG. 36, the power supply module 80 comprises at least two power IC dies 203B, a top substrate 202B, a bottom substrate 201B, and the inductor pack 206 which is sandwiched between the top substrate 202B and the bottom substrate 201B, wherein at least one cavity 290 is formed below the inductor pack 206 and the bottom substrate 201B. The embodiment of FIG. 36 shows one cavity 290 only for illustration purposes, and one with ordinary skills in the art should understand that the power supply module 80 may also have more cavities disposed below the inductor pack 206. The top substrate 202B has a bottom surface attached to the top surface of the inductor pack 206 and a top surface opposite its bottom surface. The bottom substrate 201B has a top surface attached to the bottom surface of the inductor pack 206 and a bottom surface opposite its top surface. Each power IC die 203B may integrate one of the power devices 103 shown in FIG. 19, which comprises the power switches M1, M2, the driver DR1, and further integrates some auxiliary circuits not shown in FIG. 19. However, one with ordinary skills in the art should understand that each power IC die 203B may also integrate more than two power switches or only one power switch. In the embodiment of FIG. 36, the power IC dies 203B are disposed on the top surface of the top substrate 202B or at least partially embedded in the top substrate 202B, and a plurality of passive devices 209B are also disposed on the top surface of the top substrate 202B.

In the example of FIG. 36, the power supply module 80 is configured for a dual-phase power converter, wherein the power supply module 80 has two power IC dies 203B and the inductor pack 206 has a magnetic core and two windings 271-272 at least partially embedded in the magnetic core, wherein the two windings 271-272 which pass through the magnetic core are drawn with dashed lines in the bottom view since they are invisible when viewed from the bottom of the power supply module 80. A first end 271-1 of the winding 271 is at least partially exposed on the top surface of the inductor pack 206 and electrically connected to a common node Sw of the power switches M1 and M2 integrated in a corresponding power IC die 203B, and the second end 271-2 is at least partially exposed on the top surface of the inductor pack 206 and electrically connected to a corresponding output voltage node Vo to provide an output voltage of the corresponding phase. The winding 272 is electrically connected in a similar way, and is not described here for brevity. In another embodiment, the power supply module 80 may also be configured for a power converter with more than two phases, so that the power supply module 80 may have more power IC dies 203B and the inductor pack 206 may have more than two windings. It is appreciated that the shape, structure, and orientations of the windings 271 and 272 are only for illustration purposes in this embodiment, and the windings 271 and 272 may be implemented by the windings shown in the embodiments which are previously described in FIGS. 21, 22, and 23, etc.

As shown in FIG. 36, the power supply module 80 further comprises a support structure 210B instead of the output capacitor layer 210 shown in the previous embodiments, while the interposer substrate layer 211 and the embedded capacitors 212 in the previous embodiments are not included in the power supply module 80A. The support structure 210B is capable of electrically connecting the power supply module 80 to an external circuit, and the cavity 290 is at least partially surrounded by the support structure 210B. In one embodiment, the cavity 290 is a void which provides space for other circuitry in a power supply system. When the power supply module 80A is utilized in the power supply system, a bottom surface of the support structure 210B is attached to a motherboard (e.g., the mainboard of the load), and passive components are disposed on the motherboard, which could be accommodated in the cavity 290. In some embodiments, the passive components may comprise capacitors (e.g., a plurality of capacitors used as output capacitors of the power supply module 80), resistors, inductors, etc. In one embodiment, the bottom substrate 201B is optional, and a top surface of the support structure 210B may be attached to the inductor pack 206 directly. In another embodiment, the inductor pack 206 is optional, i.e., the inductors may not be included in the power supply module 80.

As shown in the side view of the power supply module 80, the cavity 290 has a height H measured along the Z axis, i.e., perpendicular to the bottom substrate 201B and the top substrate 202B. In some embodiments, the height H of the cavity 290 is in a range of 0.5 mm-1 mm, which varies with the size of the passive components placed in the cavity 290. In other words, a height of the support structure 210B as measured between the bottom surface of the support structure 210B and the top surface of the support structure 210B is in a range of 0.5 mm-1 mm.

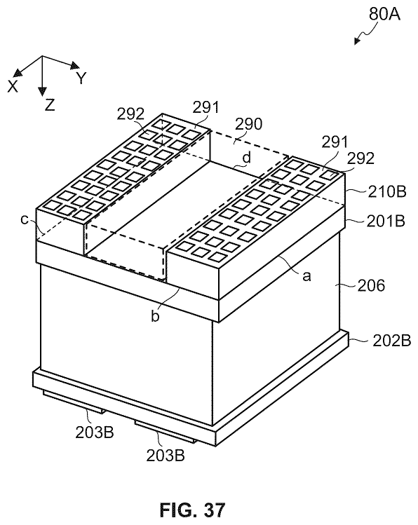

FIG. 37 schematically shows a 3D view of a power supply module 80A in accordance with an embodiment of the present invention. In FIG. 37, the power supply module 80A is placed upside down to show the structure of the support structure 210B. For clarity of illustration, the inductor pack 206 is shown in a simplified way in FIG. 37, and some components not necessary to the understanding of this embodiment (e.g., the passive devices 209B and the connector 204, etc.) are not shown in FIG. 37. In the embodiment of FIG. 37, the support structure 210B comprises at two support PCBs 291, and the cavity 290 (shown by a dashed box) is partially surrounded by the support PCBs 291. Specifically, the bottom surface of the bottom substrate 201B has at least four edges (e.g., four edges a, b, c, and d as shown in the example of FIG. 37), and the two support PCBs 291 are disposed along two opposite edges (i.e., the edges a and c) of the bottom substrate 201B respectively. Therefore, the cavity 290 of the power supply module 80A forms an open space when utilized on the motherboard. However, one with ordinary skills in the art should understand that the structure of the cavity 290 is not limited to the example shown in FIG. 37. In one example, the cavity 290 may also form a substantially enclosed space when utilized on the motherboard, as will be further described in the following embodiments.

In some embodiments, a projection area of the support structure 210B on the bottom surface of the top substrate 202B is smaller than 50% of an area of the bottom surface of the top substrate 202B. In other words, an area of the cavity 290 measured in the XY plane is larger than 50% of the area of the bottom surface of the top substrate 202B to accommodate sufficient capacitors. The bottom surface of the support structure 210B serves as a bottom surface of the power supply module 80A. The bottom surface of the support structure 210B has a plurality of pads 292 for external connections. It is to be noted that not all of the plurality of pads 292 are labeled in FIG. 37 for clarity of illustration. One with ordinary skills in the art should understand that the number and layout of the plurality of pads 292 are not limited to the example shown in FIG. 37.

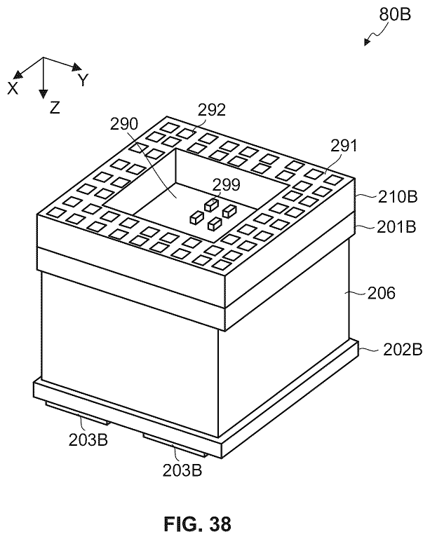

FIG. 38 schematically shows a 3D view of a power supply module 80B in accordance with an embodiment of the present invention. It is to be noted that some components of the power supply module 80B are same with those of the power supply module 80A, which will not be illustrated here for brevity. The power supply module 80B is different from the power supply module 80A in that the support structure 210B of the power supply module 80B has only one support PCB 291. In the embodiment of FIG. 38, the support structure 210B comprises a support PCB 291 formed by cutting out a center region of a PCB, and the cut region forms the cavity 290. In the embodiment of FIG. 38, the cavity 290 (e.g., the cut region) has a cuboid shape. One with ordinary skills in the art should understand that the shape of the cavity 290 is not limited to the example shown in FIG. 37, other suitable shapes (e.g., cylinders, etc.) may also be applied to the cavity 290. In one embodiment, the power supply module 80B further has a plurality of passive components 299 (e.g., input capacitors, etc.) disposed on the bottom surface of the bottom substrate 201B to make full use of the space provided by the cavity 290. In the embodiment of FIG. 38, the cavity 290 is surrounded by the support structure 210B on all sides in the XY plane and forms a substantially enclosed space when the power supply module 80B is mounted on the motherboard.

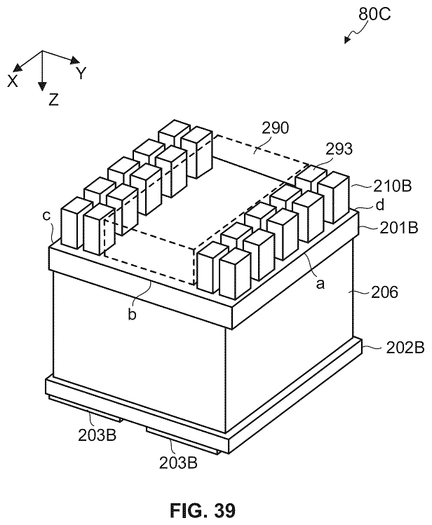

FIG. 39 schematically shows a 3D view of a power supply module 800 in accordance with an embodiment of the present invention. In the embodiment of FIG. 39, the support structure 210B is formed by a plurality of connecting pillars 293 which are configured to transmit signals and deliver power. For clarity of illustration, the inductor pack 206 is shown in a simplified way in FIG. 39, and some components not necessary to the understanding of this embodiment are not shown in FIG. 39. In FIG. 39, the power supply module 80C is placed upside down to show the structure of the support structure 210B. Note that not all of the connecting pillars 293 are labeled in FIG. 39 for clarity of illustration. In the embodiment of FIG. 39, the plurality of connecting pillars 293 are disposed on (e.g., soldered to) the bottom surface of the bottom substrate 201B for external connections. For example, when the power supply module 80C is disposed on the motherboard of a power supply system, the plurality of connecting pillars 293 are attached between the motherboard and the bottom substrate 201B to provide electrical connections between the load and the power supply module 80C. The cavity 290 (shown by a dashed box) in FIG. 39 may not be surrounded by the support structure 210C on all sides in the XY plane. Specifically, the bottom surface of the bottom substrate 201B has the four edges a, b, c, and d, and the plurality of connecting pillars 293 are disposed along at least two of the at least four edges to form the cavity 290. For example, as shown in FIG. 39, the plurality of connecting pillars 293 are disposed along two opposite edges (i.e., the edges a and c) of the bottom substrate 201B.

As mentioned before, the height of the cavity 290 is in the range of 0.5 mm-1 mm. In other words, in the embodiment of FIG. 39, each of the plurality of connecting pillars 293 has a height in the range of 0.5 mm-1 mm. As mentioned before, the projection area of the support structure 210B on the bottom surface of the top substrate 202B is smaller than 50% of the area of the bottom surface of the top substrate 202B, and specifically, in the embodiment of FIG. 39, the projection area of the plurality of connecting pillars 293 on the bottom surface of the top substrate 202B is smaller than 50% of the area of the bottom surface of the top substrate 202B.

One with ordinary skills in the art should understand that the layout of the plurality of connecting pillars 293 is not limited to the example of FIG. 39. In another embodiment, the connecting pillars 293 may also be disposed along all of the four edges a, b, c, and d of the bottom substrate 201B. In one embodiment, the connecting pillars 293 are made of metal with high electrical conductivity, e.g., the connecting pillars 293 comprises copper blocks. Although the connecting pillars 293 shown in the example of FIG. 39 are cuboids, it should be appreciated that any other suitable shapes of the connecting pillars 293 is applicable to the present disclosure.

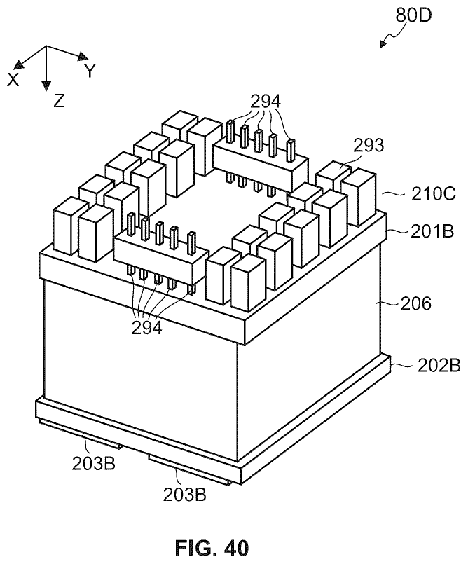

FIG. 40 schematically shows a 3D view of a power supply module 80D in accordance with an embodiment of the present invention. Compared with the power supply module 80C shown in FIG. 39, the support structure 210B of the power supply module 80D further comprises a plurality of connecting pillars 294. In the embodiment of FIG. 40, the plurality of connecting pillars 294 comprises signal pins made by metal pillars which are configured to transmit signals between the power supply module 80D and external circuits, while the plurality of connecting pillars 293 are configured for power delivery. For example, the plurality of connecting pillars 294 are configured to transmit temperature monitoring signals and current monitoring signal of the power IC dies 203B, and PWM signals for controlling the power IC dies 203B (e.g., the control signals 105 shown in FIG. 26), etc., and the plurality of connecting pillars 293 are configured to receive the input voltage Vin, provide the first output voltage and the second output voltage, and provide the reference ground, etc. In the embodiments of the present disclosure, the plurality of connecting pillars 293 are thicker than the plurality of connecting pillars 294. In the example of FIG. 40, the plurality of connectors 294 form at least one pin header soldered on the bottom surface of the bottom substrate 201B, and it is appreciated that each of the plurality of connectors 294 may also be disposed discretely.

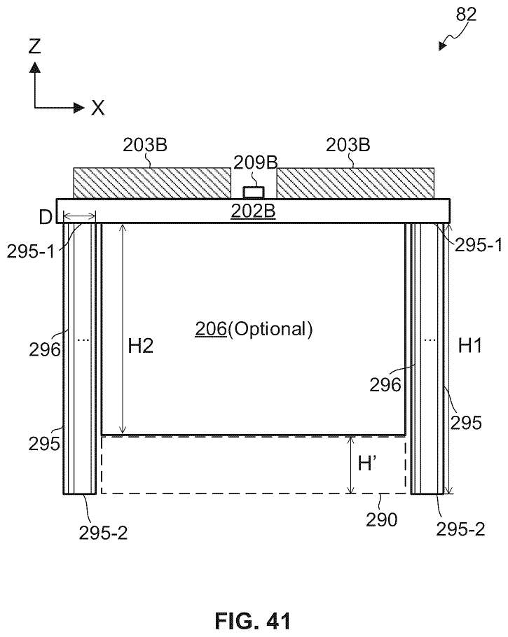

FIG. 41 schematically shows a side view of a power supply module 82 in accordance with an embodiment of the present invention. In the embodiment of FIG. 41, the support structure 210B shown in the previous embodiments is not included in the power supply module 82, and the power supply module 82 comprises two vertical PCBs 295 instead. The vertical PCBs 295 are disposed below the top substrate 202B vertically, wherein each of the vertical PCBs 295 has a plurality of PCB layers 296 (represented by vertical lines in FIG. 41) perpendicular to the XY plane (e.g. perpendicular to the bottom surface of the top PCB 202). Each of the vertical PCBs 295 has an upper terminal surface 295-1 attached to the bottom surface of the top substrate 202B and a lower terminal surface 295-2 for electrically connecting the power supply module 82 to an external circuit, wherein the lower terminal surface 295-2 is opposite the upper terminal surface 295-1. For example, the lower terminal surfaces 295-2 of the vertical PCBs 295 are soldered to the motherboard when the power supply module 82 is utilized in a power supply system. In the embodiment of FIG. 41, each of the vertical PCBs 295 has a height H1 which is larger than a height H2 of the inductor pack 206, wherein the height H1 and the height H2 are measured along the Z axis, i.e., the height H1 is measured from the lower terminal surface 295-2 of each vertical PCB 295 to the upper terminal surface 295-1 of each vertical PCB 295, and the height H2 is measured from the bottom surface of the inductor pack 206 and the top surface of the inductor pack 206. In some embodiments, a difference between the height H1 and the height H2 (i.e., H1−H2) is in a range of 0.5 mm-1 mm. In other words, a height H′ of the cavity 290 is in the range of 0.5 mm-1 mm. In one embodiment, each of the vertical PCBs 295 has a thickness D which is on the order of millimeters, e.g., in a range of 1 mm-3 mm.

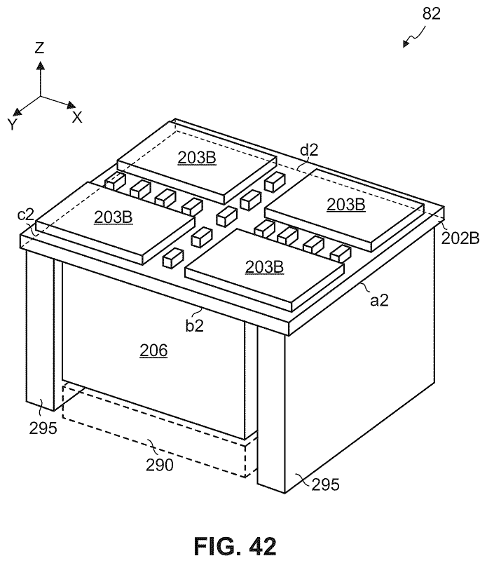

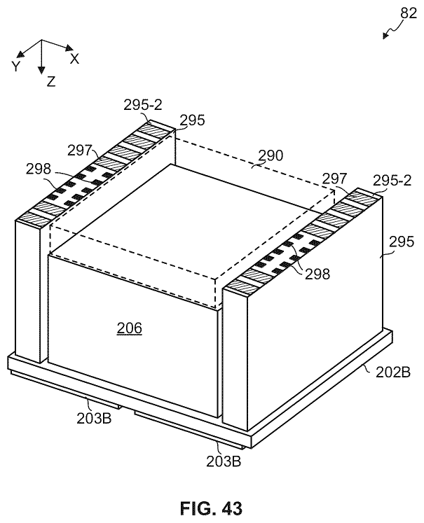

FIG. 42 schematically shows a 3D view of the power supply module 82 of FIG. 41 in accordance with an embodiment of the present invention. FIG. 43 schematically shows a 3D view of the power supply module 82 of FIG. 41 in accordance with an embodiment of the present invention and taken from another perspective. In the embodiment of FIGS. 41-43, the power supply module 82 is a four-phase power supply module with four pair of power switches (e.g. four power IC dies 203B with each power IC die 203B integrating one pair of power switches) integrated in the top substrate 202B, and the inductor pack 206 has four windings. Similar to the power supply modules 80A and 80C, in the XY plane, the cavity 290 is not surrounded by the vertical PCBs 295 on all sides. Specifically, as shown in FIG. 42, the bottom surface of the top substrate 202B has four edges a2, b2, c2, and d2, and the two vertical PCBs 295 are disposed along the two opposite edges a2 and c2 respectively. Therefore, the two vertical PCBs 295 are substantially parallel with each other, the inductor pack 206 is disposed between the two vertical PCBs 295 in a horizontal direction, and the cavity 290 below the inductor pack 206 is formed between the two vertical PCBs 29. However, it is appreciated that the number and layout of the vertical PCBs 295 are not limited to the example of FIGS. 41-43. The vertical PCBs 295 may have a different layout and the power supply module 80D may also comprise more than two vertical PCBs or only one vertical PCB. For example, the power supply module 80D may comprise four vertical PCBs 295 surrounding the inductor pack 206 to form the cavity 290. In the embodiment of FIGS. 41-43, a projection area of the inductor pack 206 on the bottom surface of the top substrate 202B is larger than 50% of an area of the bottom surface of the top substrate 202B to form the cavity 290 which is sufficiently large for accommodating the passive devices.

As shown in FIG. 43, each of the vertical PCBs 295 has a plurality of pads 297 and a plurality of pads 298 on its lower terminal surface 295-2. In FIG. 43, the plurality of pads 297 are shown by shaded blocks and the plurality of pads 298 are shown by black blocks. As shown in FIG. 43, an area of each of the plurality of pads 297 is larger than an area of each of the plurality of pads 298, therefore, the plurality of pads 298 are configured for transmitting signals between the power supply module 82 and external circuits, and the plurality of pads 297 are configured for power delivery. For example, the plurality of pads 298 are configured to transmit the temperature monitoring signals and the current monitoring signal of the power IC dies 203B, and the PWM signals for controlling the power IC dies 203B, etc., and the plurality of pads 297 are configured to receive the input voltage Vin, provide the first output voltage and the second output voltage, and provide the reference ground, etc. When utilized in the power supply system, the power supply module 82 is soldered to the motherboard via the plurality of pads 297 and the plurality of pads 298. One with ordinary skills in the art should understand that the shapes and layout of the plurality of pads 297 and the plurality of pads 298 is not limited to the example shown in FIG. 43.

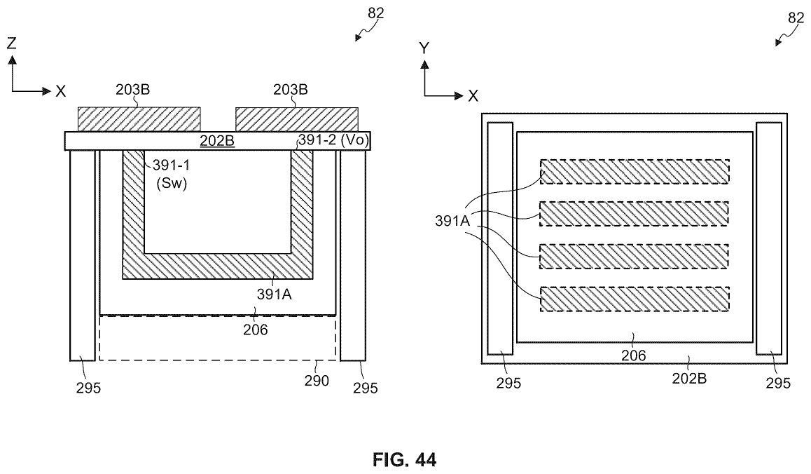

FIG. 44 schematically shows a cross-sectional view and a bottom view of the power supply module 82 of FIG. 41 in accordance with an embodiment of the present invention. In the embodiment of FIG. 44, the inductor pack 206 comprises four windings 391A at least partially embedded in the magnetic core, the four windings 391A pass through the magnetic core, and each winding 391A has a first end 391-1 and a second end 391-2. As shown in FIG. 44, each winding 391A has a “U” shape, and the first end 391-1 and the second end of each winding 391A are at least partially exposed on the top surface of the inductor pack 206. The first end 391-1 of each winding 391A is electrically connected to the common node Sw of the power switches M1 and M2 integrated in a corresponding power IC die 203B via the top substrate 202B, and the second end 391-2 of each winding 391A is electrically connected to the corresponding output voltage node Vo to provide an output voltage of the corresponding phase. In one embodiment, the second end 391-2 of each winding 391A is electrically connected to the lower terminal surface of at least one of the vertical PCBs 295, thus providing the output voltage of the corresponding phase via the plurality of pads 297.

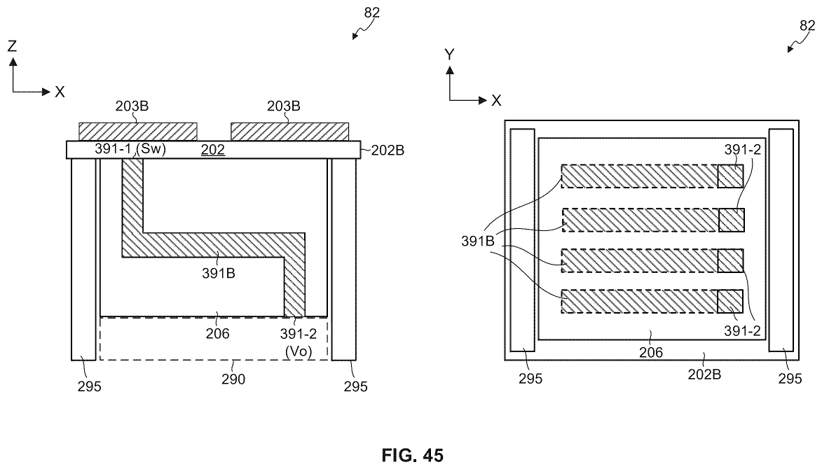

FIG. 45 schematically shows a cross-sectional view and a bottom view of the power supply module 82 of FIG. 41 in accordance with another embodiment of the present invention. In the embodiment of FIG. 45, the inductor pack 206 comprises four windings 391B at least partially embedded in the magnetic core, the four windings 391B pass through the magnetic core, and each winding 391B has the first end 391-1 and the second end 391-2. The first end 391-1 of each winding 391B is electrically connected to the common node Sw of the power switches M1 and M2 integrated in a corresponding power IC die 203B via the top substrate 202B, and the second end 391-2 is electrically connected to the corresponding output voltage node Vo to provide an output voltage of the corresponding phase. As shown in FIG. 45, the first end 391-1 of each winding 391B is at least partially exposed on the top surface of the inductor pack 206 while the second end 391-2 of each winding 391B is at least partially exposed on the bottom surface of the inductor pack 206. Therefore, in the embodiment of FIG. 45, the output voltage of each phase is provided on the bottom surface of the inductor pack 206 instead of the lower terminal surface of the vertical PCBs 295. In one embodiment, the power supply module 82 may further comprise a plurality of connecting pillars attached to the second ends of the windings 391 to electrically connect the output voltage of each phase to the motherboard when the power supply module 82 is utilized in a power supply system.

It is appreciated that the shape, structure, and orientations of the windings 391A and 391B are only for illustration purposes in the embodiments of FIG. 44 and FIG. 45, and the windings 391A and 391B may be implemented by the windings shown in the embodiments which are previously described in FIGS. 21, 22, and 23, etc.

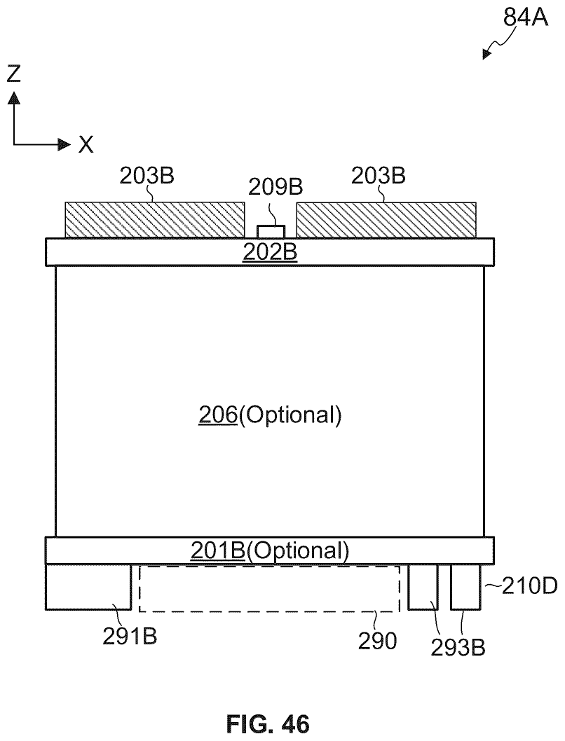

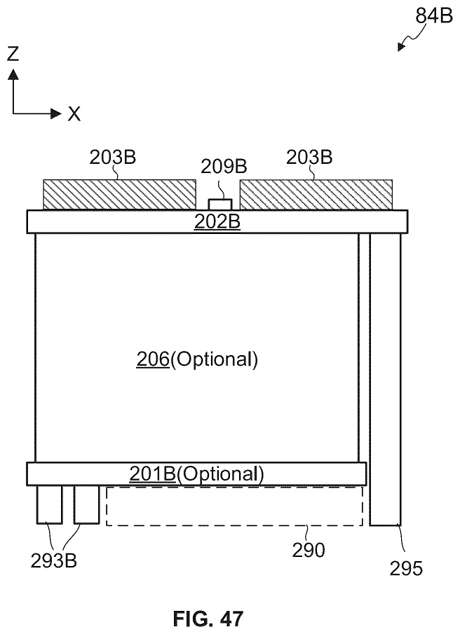

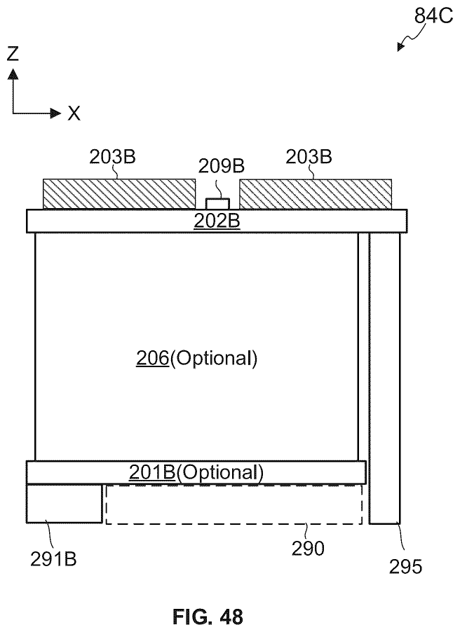

In some embodiments, two or more structures of the support PCB, the connecting pillars, the vertical PCB, and any other suitable structures may be combined together to form the cavity 290. FIG. 46 schematically shows a side view of a power supply module 84A in accordance with an embodiment of the present invention. As shown in FIG. 46, a support layer 210D comprises at least one support PCB 291B and a plurality of connecting pillars 293B to form the cavity 290. FIG. 47 schematically shows a side view of a power supply module 84B in accordance with an embodiment of the present invention. FIG. 48 schematically shows a side view of a power supply module 84C in accordance with an embodiment of the present invention. In the embodiments of FIG. 47 and FIG. 48, each of the power supply module 84B and the power supply module 84C comprises a vertical PCB 295 and a support structure, and the cavity 290 is formed between the support structure and the vertical PCB 295. The support structure comprises a plurality of connecting pillars 293B as shown in FIG. 47 and the support structure comprises a support PCB 291B as shown in FIG. 48. Similar to the power supply module 80 shown in FIG. 36, the bottom substrate 201B and the inductor pack 206 of the power supply modules 84A-84C may also be optional.

Although in each of the embodiments shown in FIGS. 36-48, each of the power supply modules 80A-80D, 82, and 84A-84C has one cavity 290, one with ordinary skills in the art should understand that a power supply module may also comprise a plurality of cavities.

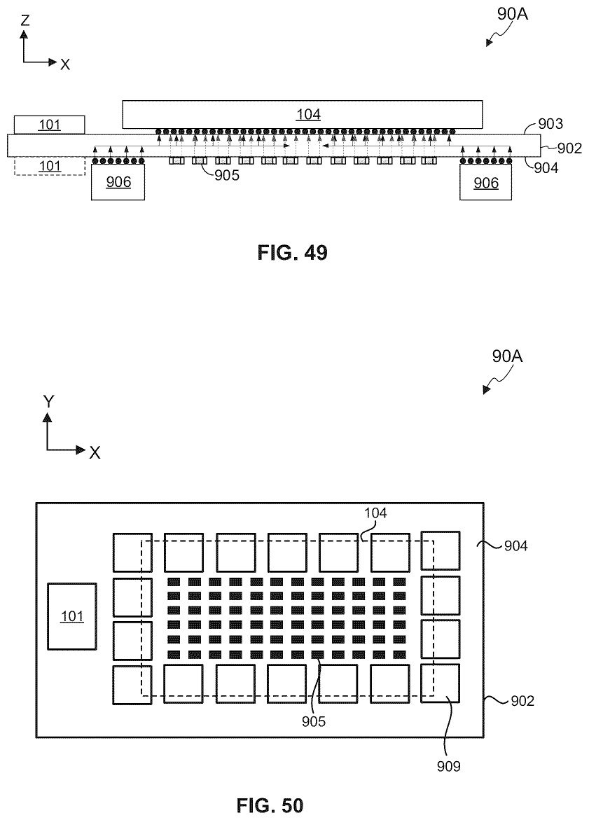

In a power supply system, at least one power supply module according to the embodiments of the present invention is configured to provide power to a load. FIG. 49 shows a cross-sectional view of a physical layout of a power supply system 90A in accordance with an embodiment of the present invention. FIG. 50 shows a bottom view of the physical layout of the power supply system 90A in accordance with an embodiment of the present invention. In the power supply system 90A, at least one power supply module 906 provides power to the load 104. Specifically, in the embodiment of FIGS. 49-50, the power supply system 90A comprises a plurality of power supply modules 906. Each power supply module 906 can be implemented by the power supply module 20A as described above, wherein the first output voltage and the second output voltage of all the power supply modules 906 are electrically connected together to provide an output voltage to the load 104. The plurality of capacitors 905 are configured as output capacitors of the power supply modules 906. In another embodiment, each power supply module 906 may also be implemented by a power supply module having more than two phases with no output capacitors integrated. The power supply module 90A further comprises a controller 101 which may be placed on the first surface 903 or on the second surface 904 of the motherboard 902. The load 104 is disposed on a first surface 903 of a motherboard 902. The plurality of power supply modules 906 and a plurality of capacitors 905 (only one capacitor 905 is labeled for clarity of illustration) are disposed on a second surface 904 of the motherboard 902, wherein the second surface 904 is opposite to the first surface 903.

In one embodiment, the at least one power supply module 906 and the plurality of capacitors 905 are soldered to the motherboard 902, and the load 104 is disposed on a first surface 903 of the motherboard 902, e.g., through associate socket and substrate, wherein the black dots in FIG. 49 represent solder balls. It is to be noted that FIG. 49 is not drawn to scale, and in real applications, the solder balls may be too small to be identified in the cross-sectional view of the power supply system 90A. One with ordinary skill in the art should understand that the cross-sectional view of the power supply system 90A in FIG. 50 show eighteen power supply modules 906 only for illustration purpose, and a power supply system may have more or fewer power supply modules 906 according to different applications. Specifically, in one embodiment, a power supply system may have only one power supply module 906. Similarly, the number of capacitors included in the plurality of capacitors 905 is not limited to the example of FIG. 50 either.

In the embodiment of FIG. 49 and FIG. 50, both the plurality of power supply modules 906 and the plurality of capacitors 905 are placed on an opposite side from the load 104, however, since the plurality of capacitors 905 are surrounded by the plurality of power supply modules 906, only the plurality of capacitors 905 are located right across from the load 104, as shown in FIG. 50. Therefore, as shown in FIG. 49, conductive paths between the plurality of capacitors 905 and the load 104 (shown by dashed lines with arrows) could be short, e.g., perpendicular to the motherboard 902, while power delivery paths of the power supply modules 906 (shown by solid lines with arrows) are long. The long power delivery paths of the power supply modules 906 introduce additional resistance, which causes large power loss.

FIG. 51 shows a cross-sectional view of a physical layout of a power supply system 90B in accordance with another embodiment of the present invention. In the example of FIG. 51, at least one power supply module 907 provides power to the load 104, and only one power supply module 907 is labeled in FIG. 51 for clarity of illustration. The load 104 is disposed on the first surface 903 of the motherboard 902. One with ordinary skills in the art should understand that the number of the power supply modules 907 is not limited to the example of FIG. 51, more or fewer power supply modules 907 may be employed in a power supply system 90B.

As shown in FIG. 51, each of the power supply modules 907 can be implemented by the power supply module 20B shown in FIGS. 27-32, comprising a power block (formed by the components of the power supply module 20B except the embedded capacitors 212), the interposer substrate layer 211 and the embedded capacitors 212 which are configured as the output capacitors of the corresponding power supply module 907. In one embodiment, the power block and the embedded capacitors 212 are soldered to the interposer substrate layer 211. One with ordinary skills in the art should understand that each of the power supply modules 907 may also be implemented by the power supply module 20C shown in FIG. 33, or by a power supply module having more than two phases.

Compared with the embodiment of FIG. 49, the power supply modules 907 are placed closer to the load 104 than the power supply modules 906 do. Therefore, the power delivery paths of the power supply module 907 (shown by solid lines with arrows) is shorter than the power delivery paths of the power supply module 906, e.g., the power delivery paths of the power supply module 907 are perpendicular to the motherboard 902 as shown in FIG. 51. The shorter power delivery paths reduce power loss, which improves the efficiency of the power supply system 90B. However, the conductive paths between the output capacitors (implemented by the embedded capacitors 212) and the load 104 (shown by dashed lines with arrows) are longer than the conductive paths between the plurality of capacitors 905 and the load 104 shown in the embodiment of FIG. 49 since the conductive paths between the embedded capacitors 212 and the load 104 comprise additional routing in the interposer substrate layers 211, causing larger impedance between the output capacitors and the load 104. The large impedance between the output capacitors and the load 104 is undesirable for transient response of the power supply system 90B.

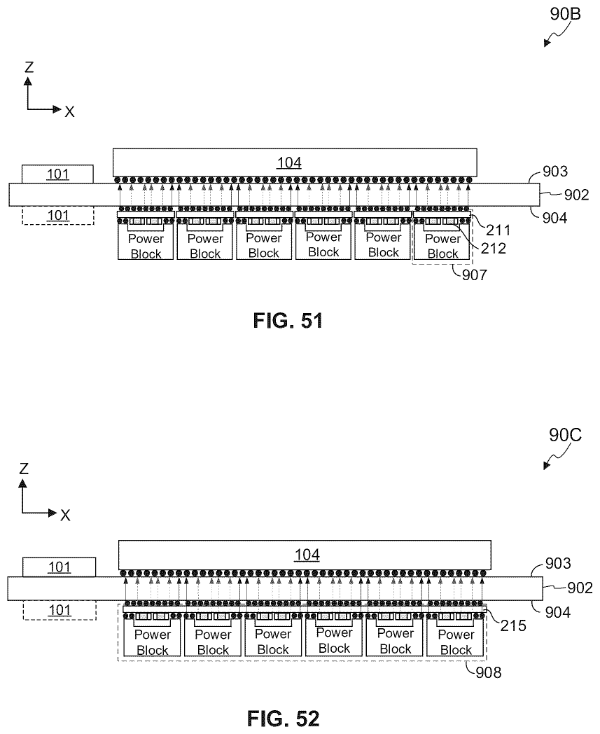

FIG. 52 shows a cross-sectional view of a physical layout of a power supply system 90C in accordance with yet another embodiment of the present invention. The power supply system 90C is similar to the power supply system 90B and is distinguished for comprising a power supply module 908 instead of the at least one power supply module 907. The power supply module 908 has a plurality of power blocks soldered to an interposer substrate layer 215. Specifically, the power supply module 908 may be implemented by the power supply module 20D as shown in FIG. 35. The power supply system 90C shows similar features with the power supply system 90B since the power delivery paths of the power supply module 908 and the conductive paths between the output capacitors and the load 104 are same as those described in the embodiment of FIG. 51, which will not be discussed here for brevity.

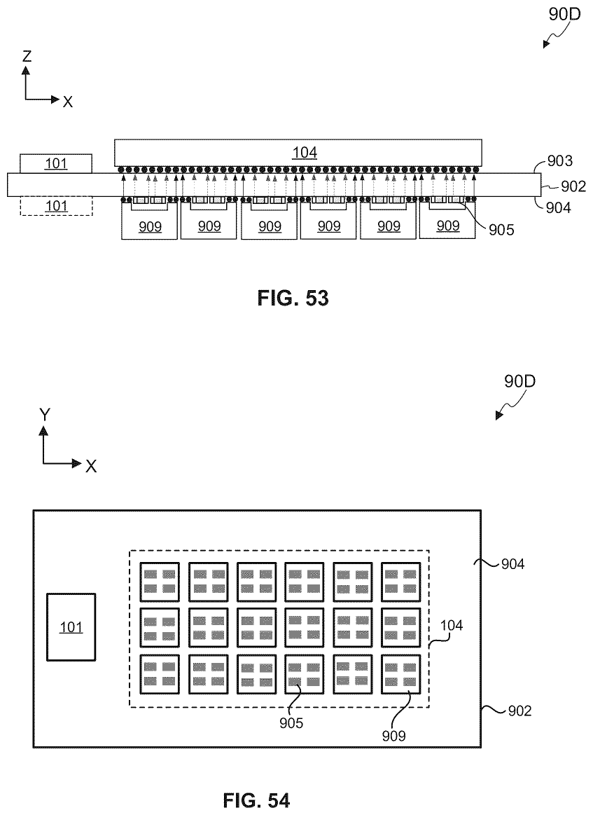

FIG. 53 shows a cross-sectional view of a physical layout of a power supply system 90D in accordance with yet another embodiment of the present invention. FIG. 54 shows a bottom view of the physical layout of the power supply system 90D in accordance with an embodiment of the present invention. In the example of FIGS. 53-54, a plurality of power supply modules 909 provides power to the load 104. One with ordinary skills in the art should understand that the cross-sectional view of the power supply system 90D in FIG. 54 show eighteen power supply modules 909 only for illustration purposes, and a power supply system may have more or fewer power supply modules 909 according to different applications. Specifically, in one embodiment, a power supply system may have only one power supply module 909. Similarly, the number of capacitors included in the plurality of capacitors 905 is not limited to the example of FIG. 54 either. In the embodiment of FIG. 49 and FIG. 50, a projection of each power supply module 909 on the second surface 904 of the motherboard 902 at least partially overlaps with a projection of the load 104 on the second surface 904 of the motherboard 902.

As shown in FIG. 49 and FIG. 50, the load 104 is disposed on the first surface 903 of the motherboard 902. The power supply modules 909 and the plurality of capacitors 905 (only one capacitor 905 is labeled for clarity of illustration) are disposed on the second surface 904 of the motherboard 902, wherein the plurality of capacitors 905 are configured as output capacitors of the plurality of power supply modules 909, and in one example, each power supply module 909 may be implemented by one of the power supply module 80A-80D, 82, and 84A-84C, wherein each power supply module 909 has a cavity at bottom to accommodate corresponding ones of the plurality of capacitors 905. For example, each power supply module 909 is implemented by the power supply module 82, and the output voltages of the four phases of all the power supply modules 909 are electrically connected together and electrically connected with the plurality of capacitors 905 to provide the output voltage to the load 104, and the plurality of capacitors 905 are further electrically connected to the reference ground. In another embodiment, the inductor pack 206 may not be included in each power supply module 909, and the inductors of the power supply system 90D may be disposed on the motherboard 902 individually, e.g., disposed beside the power supply modules 909 or disposed above the power supply modules 909.

Compared with the power supply system 90B and 90C, the conductive paths between the plurality of capacitors 905 and the load 104 shown in FIG. 53 (shown by dashed lines with arrows) are short since no interposer substrate layer is utilized in the power supply system 90D, which is similar to the power supply system 90A. Besides, compared with the power supply system 90A, in the embodiment of FIG. 53 and FIG. 54, the plurality of power supply modules 909 are also located right across the load 104. Therefore, the power delivery paths of each power supply module 909 could also be short, which is similar to the power supply system 90B and 90C. Therefore, in the embodiment of FIG. 53 and FIG. 54, the power supply system 90D shows improved efficiency and transient response because the power supply modules 909 provide the power delivery paths with small resistance and also make the impedance between the output capacitors and the load 104 small.

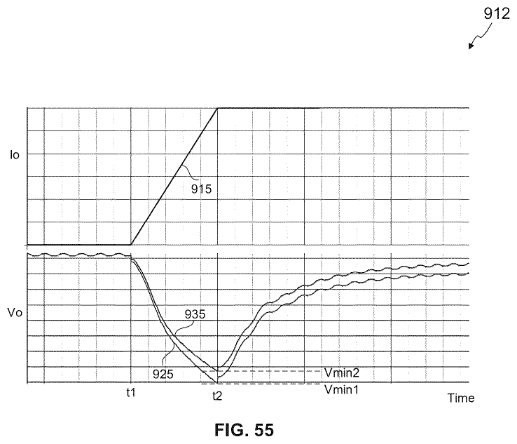

FIG. 55 shows waveforms 912 of an output current and output voltages in accordance with an embodiment of the present invention. As shown in FIG. 55, a curve 915 shows an output current lo provided to a load, e.g., the load 104 of FIGS. 47-51. Curves 925 and 935 respectively show output voltages Vo1 and Vo2 provided to the load 104 in the power supply systems 90B and 90D, wherein the output voltages Vo1 and Vo2 vary with the output current Io. It is to be noted that in the embodiment of FIG. 55, the power supply systems 90B and 90D mentioned here show different physical layouts based on FIGS. 49 and 51, but have same number of phases (i.e., same number of power blocks) and same number of output capacitors to compare their transient response abilities. As shown in FIG. 55, at a time t1, the output current Io starts to increase, and the output voltages Vo1 and Vo2 start to decrease. At a time t2, the output current Io stops increasing, and the output voltages Vo1 and Vo2 stops decreasing. Specifically, the output voltage Vo1 reaches a minimum voltage level Vmin1, and the output voltage Vo2 reaches a minimum voltage level Vmin2. After the time t2, as the output current Io becomes stable, the output voltages Vo1 and Vo2 increases. As shown in FIG. 55, the output voltage Vo2 provided in the power supply system 90D decreases more slowly than the output voltage Vo1 provided in the power supply system 90B before the time t2, and the minimum voltage level Vmin2 of the output voltage Vo2 is larger than the minimum voltage level Vmin1 of the output voltage Vo1. In other words, the output voltage Vo2 has a smaller undershoot. Therefore, it is seen from FIG. 55 that the power supply system 90D shows faster transient than the power supply system 90B.

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

What is claimed is:

1. A power supply module, comprising:
an inductor pack having a magnetic core, a first winding and a second winding, wherein the first winding and the second winding pass through the magnetic core;
a top substrate disposed above the inductor pack, wherein the top substrate has a bottom surface attached to the inductor pack;
a first power IC die electrically connected to the first winding and a second power IC die electrically connected to the second winding, wherein the first power IC die and the second power IC die are disposed above the inductor pack;
a support structure disposed below the inductor pack, wherein the support structure is capable of electrically connecting the power supply module to an external circuit; and
a cavity formed below the inductor pack, wherein the cavity is at least partially surrounded by the support structure, and the cavity is capable of accommodating passive components.

2. The power supply module of claim 1, wherein:
the first power IC die comprises a first pair of power switches, and the second power IC die comprises a second pair of power switches; and wherein
the first winding is electrically connected between a common node of the first pair of power switches and a first output voltage node to provide a first output voltage, and the second winding is electrically connected between a common node of the second pair of power switches and a second output voltage node to provide a second output voltage.

3. The power supply module of claim 1, wherein a height of the support structure as measured perpendicular to the bottom surface of the top substrate is in a range of 0.5 mm-1 mm.

4. The power supply module of claim 1, further comprising a bottom substrate disposed between the inductor pack and the support structure.

5. The power supply module of claim 1, wherein:
the first power IC die and the second power IC die are disposed on or embedded in the top substrate.

6. The power supply module of claim 1, wherein:
the support structure comprises at least one support PCB; and wherein
the power supply module further comprises a plurality of pads disposed on a bottom surface of the at least one support PCB for electrically connecting the power supply module to an external circuit.

7. The power supply module of claim 1, further comprising:
a bottom substrate disposed below the inductor pack, wherein the bottom substrate has a bottom surface facing away from the inductor pack; wherein
the support structure comprises a plurality of connecting pillars disposed on the bottom surface of the bottom substrate.

8. The power supply module of claim 7, wherein:
the bottom surface of the bottom substrate has a plurality of edges, and the plurality of connecting pillars are disposed along at least two of the plurality of edges.

9. The power supply module of claim 7, wherein:
a first one of the plurality of connecting pillars is capable of receiving an input voltage, wherein the input voltage is provided to the first power IC die and the second power IC die;
a second one of the plurality of connecting pillars is capable of providing a first output voltage; and
a third one of the plurality of connecting pillars is capable of providing a second output voltage; and
a fourth one of the plurality of connecting pillars is electrically connected to a reference ground.

10. The power supply module of claim 1, further comprising:
a vertical PCB disposed below the top substrate, having an upper terminal surface attached to a bottom surface of the top substrate and a lower terminal surface opposite the upper terminal surface; wherein
the support structure has a bottom surface facing away from the inductor pack; and wherein
the cavity is formed between the support structure and the vertical PCB.

11. The power supply module of claim 1, wherein:
a projection area of the support structure on the bottom surface of the top substrate is smaller than 50% of an area of the bottom surface of the top substrate.

12. A power supply module, comprising:
an inductor pack having a magnetic core, a first winding and a second winding, wherein the first winding and the second winding are at least partially embedded in the magnetic core, and each of the first winding and the second winding has a first end and a second end;
a top substrate disposed above the inductor pack; and
a first pair of power switches and a second pair of power switches electrically connected between an input voltage and a reference ground, a common node of the first pair of power switches is electrically connected to the first end of the first winding, a common node of the second pair of power switches is electrically connected to the first end of the second winding; wherein
the first pair of power switches and the second pair of power switches are disposed on or embedded in the top substrate; and wherein
a cavity is formed below the inductor pack for accommodating passive components.

13. The power supply module of claim 12, wherein:
a height of the cavity as measured perpendicular to the bottom surface of the top substrate is in a range of 0.5 mm-1 mm.

14. The power supply module of claim 12, further comprising:
a bottom substrate disposed below the inductor pack, wherein the cavity is formed below the bottom substrate.

15. The power supply module of claim 12, further comprising:
a support structure disposed below the inductor pack; wherein
the support structure is capable of electrically connecting the power supply module to an external circuit; and wherein
the cavity is at least partially surrounded by the support structure.

16. A power supply system, comprising:
a motherboard having a first surface and a second surface opposite each other;
a load disposed on the first surface of the motherboard; and
a power supply module and a plurality of capacitors disposed on the second surface of the motherboard, each of the plurality of capacitors having a first end and a second end; wherein
the power supply module comprises:
a top substrate;
a first pair of power switches and a second pair of power switches disposed on or embedded in the top substrate, wherein the first pair of power switches and the second pair of power switches are electrically connected between an input voltage and a reference ground, a common node of the first pair of power switches is electrically connected to a first end of a first inductor, and a common node of the second pair of power switches is electrically connected to a first end of a second inductor; and
at least one cavity formed below the top substrate, wherein the plurality of capacitors are disposed in the at least one cavity; wherein
the first ends of the plurality of capacitors are electrically connected to the reference ground, and a second end of the first inductor and a second end of the second inductor are electrically connected to the second ends of the plurality of capacitors to provide an output voltage to the load.

17. The power supply system of claim 16, further comprising:
a controller disposed on the motherboard; wherein
the controller is capable of providing a plurality of switching control signals to the power supply module to control the first pair of power switches and the second pair of power switches.

18. The power supply system of claim 16, further comprising:
an inductor pack having a magnetic core, a first winding and a second winding, wherein the first winding and the second winding are at least partially embedded in the magnetic core; wherein
the first inductor is formed by the first winding and the magnetic core, and the second inductor is formed by the second winding and the magnetic core.

19. The power supply system of claim 16, wherein a projection of the power supply module on the second surface of the motherboard at least partially overlaps with a projection of the load on the second surface of the motherboard.

20. The power supply system of claim 16, wherein:
the power supply module further comprises a support structure disposed below the inductor pack; and wherein
the at least one cavity is at least partially surrounded by the support structure.
